(19) United States
(12) Patent Application Publication
(10) Pub. No.: US 2026/0245779 A1
(43) Pub. Date: Aug. 20, 2026

(54) INTEGRATED CURRENT SENSOR AND ENERGY HARVESTER BASED ON MICRORESONATOR ENERGY TRANSDUCER

(71) Applicant: Schneider Electric USA, Inc., Boston, MA (US)

(72) Inventors: Adrian Abdala Rendon Hernandez, Grenoble (FR); Juan Ignacio Melecio Ramirez, North Liberty, IA (US); Collin Richard Fischels, Independence, IA (US); Austin Sean Derby, Cedar Rapids, IA (US)

(21) Appl. No.: 19/471,142

(22) PCT Filed: Mar. 27, 2024
(86) PCT No.: PCT/US2024/021612

§ 371 Date: Sep. 30, 2025

Related U.S. Application Data
(63) Continuation-in-part of application No. 18/526,390, filed on Dec. 1, 2023.
Application No. 18/526,390 is a continuation-in-part of application No. 18/367,256, filed on Sep. 12, 2023, now Pat. No. 12,571,818.
Application No. 18/367,256 is a continuation of application No. 18/367,233, filed on Sep. 12, 2023.
(60) Provisional application No. 63/456,427, filed on Mar. 31, 2023.
(60) Provisional application No. 63/456,430, filed on Mar. 31, 2023.
(60) Provisional application No. 63/529,544, filed on Jul. 28, 2023.
(60) Provisional application No. 63/538,731, filed on Sep. 15, 2023.

(51) Int. Cl. H01F 17/00; H01F 5/00; H01F 41/076; H05K 1/16

(52) U.S. Cl. CPC H01F 17/0033; H01F 5/003; H01F 41/076; H05K 1/165; H05K 2201/086

(57) ABSTRACT

An integrated multifunctional energy system is provided for measuring current flow on a conductor and/or harvesting energy. The system includes a resonator and an energy transducer. The resonator includes a magnet-suspension assembly with a suspension and a magnetodynamic volume. The suspension has a platform on which the magnetodynamic volume is connected. The suspension assembly can oscillate under an influence of a time-varying magnetic field generated by the flow of current through the conductor which is arranged in proximity and parallel or substantially parallel to the suspension assembly or component(s) thereof. A transducer is positioned around or in proximity to the magnetodynamic volume. An electromagnetic force is induced on or through the transducer by the oscillation of the volume to produce electrical energy comprising an output voltage or current that is proportional to the current flowing through the conductor. The electrical energy can be used for current flow measurement and/or harvested.

### RELATED APPLICATIONS

The present application claims the benefit of and priority to: (1) U.S. Non-Provisional patent application Ser. No. 18/367,233, filed on Sep. 12, 2023, entitled INDUCTIVE COUPLING PROXIMITY CURRENT SENSOR FOR ENERGY MEASUREMENT, which claims priority to U.S. Provisional Patent Application Ser. No. 63/456,430 filed on Mar. 31, 2023, entitled INDUCTIVE COUPLING PROXIMITY CURRENT SENSOR FOR ENERGY MEASUREMENT; (2) U.S. Provisional Patent Application Ser. No. 63/538,731, filed Sep. 15, 2023, entitled MICRO-RESONATOR FOR CURRENT SENSING, AND ENERGY MEASUREMENT AND ENERGY HARVESTING; and (3) U.S. Continuation-In-Part (CIP) Non-Provisional patent application Ser. No. 18/526,390, filed on Dec. 1, 2023, entitled REDUCED-CROSSTALK, INTEGRATED LOW-PROFILE CURRENT SENSOR PCB MODULE, which claims priority to (a) U.S. Non-Provisional patent application Ser. No. 18/367,256, filed on Sep. 12, 2023, entitled PCB TRACE CURRENT SENSOR FOR ENERGY MEASUREMENT, which claims priority to U.S. Provisional Patent Application Ser. No. 63/456,427, filed Mar. 31, 2023, entitled PCB TRACE CURRENT SENSOR FOR ENERGY MEASUREMENT PRIVATE and (b) U.S. Provisional Patent Application Ser. No. 63/529,544, filed Jul. 28, 2023, entitled REDUCED-CROSSTALK, INTEGRATED LOW-PROFILE CURRENT SENSOR PCB MODULE. The disclosures of the above-identified prior U.S. Patent Applications, in their entirety, are considered as being part of the present application, and thus, are incorporated herein by reference in their entirety.

### TECHNICAL FIELD

The present disclosure relates to circuit breakers, metering devices, wiring devices, and other devices that monitor and measure current flow, and more particularly an integrated multi-functional energy system with a micro-resonator for non-invasively monitoring current flow and/or harvesting energy.

### BACKGROUND

Modern protection devices (e.g., circuit breakers), metering devices, wiring devices, and other current flow monitoring devices that monitor and measure current flow and energy usage may have components that enable several functions not previously available in prior devices. For example, a CPU (e.g., microcontroller or MCU) in an electronic circuit breaker can allow the breaker to function as both a ground fault circuit interrupt (GFCI) device as well as an arc fault circuit interrupt (AFCI) device. The CPU can detect such faults by constantly sensing and sampling line current and monitoring these currents.

In many electronic circuit breakers and other current flow monitoring device(s) (also referred herein as “flow monitoring device(s)”), the current sensor is a current transformer that has a large number of wire coils, or windings, wrapped around a toroidal core, usually ferromagnetic material alloys. The current transformer may be optimized by adjusting the number of windings (turns), by using a ferrite core, and the like. Some circuit breakers use a so-called “coreless” current sensor, also known as a “current rate of change” or “di/dt” sensor, a “current rise time” sensor, or a Rogowski coil, where the toroidal core is non-ferromagnetic. The Rogowski coil type current sensor provides an output signal, which is a voltage that is proportional to the rate of change of the input signal, which is the line current.

However, the use of conventional current transformers as current sensors can present several design challenges. For one thing, these current transformers tend to be bulky and occupy a lot of space, making them difficult to incorporate into an already crowded electronic circuit breaker. This is especially true for miniature circuit breakers (MCB) where internal spacing is even more constrained. Furthermore, these current transformers are invasive, requiring the monitored conductor to be positioned therein and therethrough. Additional challenges also arise due to the increased mechanical complexity that typically accompanies installation of such conventional current transformers within a circuit breaker, wiring device, metering device, or other current flow monitoring device.

Accordingly, a need exists for a current sensor system (or sensing device) which is thinner, smaller, less invasive, and/or takes up less space to allow for effective installation in applications, such as for example a multi-pole miniature circuit breaker or other multi-pole circuit protective devices, with limited space. A need also exists for a current sensor system that can provide for additional functionality, including energy harvesting, to enable greater flexibility in the design and functionality of circuit breakers and other circuit protective devices.

### SUMMARY

In accordance with an embodiment, an integrated multifunctional energy system can include: a resonator comprising an oscillatable suspension assembly which includes a suspension and a magnetodynamic volume, the suspension having a platform on which the magnetodynamic volume is connected, the suspension assembly being configured to oscillate under an influence of a time-varying magnetic field generated by the flow of current through the conductor which is arranged in proximity to the suspension assembly or component(s) thereof; and a first energy transducer, positioned around or in proximity to at least a portion of the magnetodynamic volume, on or through which an electromagnetic force is induced by the oscillation of the magnetodynamic volume(s) to generate electrical energy comprising an output voltage or current that is proportional to the current flowing through the conductor.

In accordance with an embodiment(s), the magnetodynamic volume can include a permanent magnet, a magnetostrictive material or a combination thereof. The first energy transducer can include an electromechanical transducer, a piezoelectric transducer, or a magneto-electric transducer.

In accordance with an embodiment(s), the integrated multifunctional energy system can further include: at least a current sensor for sensing current flow through the conductor and an energy harvester for harvesting energy from current flow through the conductor, the current sensor and energy harvester being provided as an integrated system, wherein the resonator is a component of the current sensor, the energy harvester, or both. The integrated multifunctional energy system can further include a printed circuit board trace sensor, wherein the current sensor can include the printed circuit board trace sensor, and the energy harvester can include the resonator and the first energy transducer. Components of the current sensor and the energy harvester can be provided on the same printed circuit board substrate, or provided on different printed circuit board substrates which are connected across a flexible connector.

In accordance with an embodiment(s), the suspension assembly can further include a spacer(s) connected between the platform and the magnetodynamic volume. The suspension can further include a base or mounting frame and at least one arm, beam, segment or element connected on one end to the base or mounting frame and on another end to the platform.

In accordance with an embodiment(s), the suspension can include simple beam(s), split-anchor beam(s), serpentine beams(s), split-anchor serpentine beam(s) and/or meandering beam(s), which is connected to a base or mounting frame and the platform.

In accordance with an embodiment(s), the suspension and/or a component(s) thereof can be made of titanium or titanium alloy, aluminum or aluminum alloy, or a non-magnetic alloy.

In accordance with an embodiment(s), the electrical energy generated by the first energy transducer can be harvested and used to provide a measurement of the current flow.

In accordance with an embodiment(s), the integrated multifunctional energy system can further include: a second energy transducer for generating electrical energy from oscillation of the suspension assembly, the electrical energy generated by one of the first and second energy transducers being used for measurement of the current flow through the conductor, the electrical energy generated by the other one of the first and second energy transducers being used for harvesting energy. In various embodiments, the first energy transducer or the second energy transducer can include an electromechanical transducer, a piezoelectric transducer, or a magneto-electric transducer. In various embodiments, the first energy transducer or the second energy transducer can include the piezoelectric transducer, the piezoelectric transducer having two piezoelectric arms, segments or elements, each of which is connected at one end to the suspension or a component(s) thereof. In various embodiments, the integrated multifunctional energy system can further include: a third energy transducer or planar coil current sensor for generating electrical energy which is proportional to the current flow through the conductor, wherein the electrical energy generated by one of the first and second energy transducers is used for measurement of the current flow through the conductor in a first frequency range, and the electrical energy generated. by the third energy transducer or planar coil current sensor is used for measurement of the current flow through the conductor in a second frequency range which differs from the first frequency range.

In accordance with an embodiment(s), the integrated multifunctional energy system can further include a printed circuit board substrate or other non-conductive substrate on or to which at least the electrodynamic coil and the resonator are connected, the printed circuit board substrate or other non-conductive substrate having a hole, opening or cavity which has the electrodynamic coil and at least a portion of the magnetodynamic volume arranged therein in proximity to each other.

In accordance with an embodiment(s), the resonator can be configured for an application at or around 50 Hz or 60 Hz.

In accordance with an embodiment(s), the resonator can be a micro-resonator.

In accordance with an embodiment(s), a portion of the conductor can be arranged in proximity and in parallel or substantially parallel to the magnetodynamic volume of the suspension assembly.

In accordance with an embodiment(s), the suspension assembly or component(s) thereof can be configured to oscillate in torsional resonance under the influence of the time-varying magnetic field generated by a flow of AC current through the conductor.

In accordance with an embodiment(s), the output voltage or current is shifted by a phase offset to calibrate a measurement of the current flowing through the conductor.

In accordance with an embodiment(s), a circuit protective device can include the conductor; at least one of the integrated multifunctional energy system as described above (or herein); and a processor(s) configured to: detect for a condition or fault on a circuit of an electrical system based on the current monitored on the conductor of the circuit by the sensor system; and interrupt the flow of current on the conductor if the condition or fault is detected.

In accordance with an embodiment(s), the electrical system can be a multi-phase or pole electrical system, the conductor can include a plurality of line conductors for multi-phases or multi-poles of the electrical system, and the at least one of the integrated multifunctional energy system can include a plurality of the integrated multifunctional energy systems for the plurality of line conductors.

In accordance with an embodiment(s), a method is provided of non-invasively monitoring a flow of current flow through a conductor and/or harvesting energy due to current flow through the conductor. The method can include: providing a resonator comprising an oscillatable suspension assembly including a suspension and a magnetodynamic volume, the suspension having a platform on which the magnetodynamic volume is connected, the suspension assembly and components thereof being configured to oscillate under an influence of a time-varying magnetic field generated by the flow of current through the conductor which is arranged in proximity to the suspension assembly or component(s) thereof; and inducing an electromagnetic force on or through a first energy transducer, which is positioned around and in proximity to at least a portion of the magnetodynamic volume, to produce electrical energy comprising an output voltage or current that is proportional to the current flowing through the conductor. The resonator and the first energy transducer are integrated onto or into a printed circuit board substrate or other non-conductive substrate as part of an integrated multifunctional energy system.

In accordance with an embodiment(s), the method can further include: harvesting electrical energy which is generated from oscillation of the suspension assembly using the first energy transducer or a second energy transducer comprising an electromechanical transducer, a piezoelectric transducer, or a magneto-electric transducer.

In accordance with an embodiment(s), the method can further include: monitoring current flow through the conductor using a printed circuit board trace current sensor which is part of the integrated multifunctional energy system; and harvesting the electrical energy produced by the first energy transducer.

In accordance with an embodiment(s), the suspension assembly can be placed in proximity and in parallel or substantially parallel to the conductor, the conductor comprising a line conductor, bus bar or bonding wire which is housed in a circuit protective device.

In accordance with an embodiment(s), the magnetodynamic volume comprises a permanent magnet, a magnetostrictive material or a combination thereof.

In accordance with an embodiment(s), the method can further include: generating electrical energy, which is proportional to the current flow through, on a second energy transducer from oscillation of the suspension assembly the conductor, the electrical energy generated by one of the first and second energy transducers being used for measurement of the current flow through the conductor in a first frequency range, the electrical energy generated by the other one of the first and second energy transducers being used for harvesting energy; and inducing electrical energy, which is proportional to the current flow through the conductor, on a third energy transducer or planar coil current sensor on the printed circuit board substrate or other non-conductive substrate from an electromagnetic field generated by the current flow through the conductor, the electrical energy from the third energy transducer or planar coil current sensor being used for measurement of the current flow in a second frequency range which differs from the first frequency range.

### BRIEF DESCRIPTION OF THE DRAWINGS

FIG. 1A shows a schematic diagram illustrating an exemplary current flow monitoring device that uses an integrated multifunctional energy system(s), which can employ non-invasive, low-profile components such as mechanical resonator and an energy transducer for current monitoring and/or energy harvesting, according to embodiments of the present disclosure.

FIG. 1B shows a schematic diagram illustrating an exemplary current flow monitoring device that uses an integrated multifunctional energy system(s), which can employ non-invasive, low-profile components such as a mechanical resonator, energy transducer, and printed circuit board (PCB) trace current sensor, to perform current monitoring and energy harvesting, according to embodiments of the present disclosure.

FIG. 1C shows a schematic diagram illustrating an exemplary current flow monitoring device that uses an integrated multifunctional energy system(s), which can employ non-invasive, low-profile components such as a mechanical resonator, energy transducer, and printed circuit board (PCB) trace current sensor, to perform current monitoring and energy harvesting, according to embodiments of the present disclosure.

FIG. 2A shows a diagram of a front side of an exemplary integrated multifunctional energy system with an exemplary resonator-based current sensor and/or energy harvester, according to embodiments of the present disclosure.

FIG. 2B shows a diagram of a front side of an exemplary integrated multifunctional energy system with an exemplary PCB trace current sensor and an exemplary resonator-based energy harvester, according to embodiments of the present disclosure.

FIG. 2C shows a diagram of a front side of an exemplary integrated multifunctional energy system with an exemplary PCB trace current sensor and an exemplary resonator-based energy harvester on different PCB substrate/sections which are connected across a flexible connector, according to embodiments of the present disclosure.

FIG. 3 shows a diagram of a back side of an integrated multifunctional energy system with an exemplary resonator-based current sensor and/or energy harvester, according to embodiments of the present disclosure.

FIG. 4 shows a diagram of an exemplary suspension of a magnet-suspension assembly of a mechanical resonator for a non-invasive, low-profile current sensor and//or energy harvester of an integrated multifunctional energy system, according to embodiments of the present disclosure.

FIG. 5 shows a diagram of an exemplary suspension of a suspension assembly of FIG. 4 connected to a piezoelectric transducer for harvesting electrical energy from oscillation of the suspension assembly, according to embodiments of the present disclosure.

FIG. 6 shows a diagram of a cross-sectional view of exemplary components of a non-invasive, low-profile current sensor/energy harvester with a mechanical resonator including a magnet-suspension assembly, and energy transducer(s), according to embodiments of the present disclosure.

FIG. 7A shows a view of an exemplary current flow monitoring device such as a circuit protective device (e.g., a circuit breaker), including an integrated multifunctional energy system(s) for current monitoring and/or energy harvesting, according to embodiments of the present disclosure.

FIG. 7B shows a perspective view of an exemplary current flow monitoring device such as a circuit protective device (e.g., a circuit breaker), including an integrated multifunctional energy system(s) for current monitoring and/or energy harvesting, according to embodiments of the present disclosure.

FIG. 8A shows a graph illustrating exemplary performance under test conditions for an exemplary non-invasive, low-profile current sensor with a mechanical resonator having a magnet-suspension assembly, and an energy transducer according to embodiments of the present disclosure.

FIG. 8B shows a graph illustrating exemplary performance under test conditions for an exemplary non-invasive, low-profile PCB trace current sensor according to embodiments of the present disclosure.

FIG. 8C shows two graphs illustrating exemplary performance under different test conditions for an exemplary non-invasive, low-profile PCB trace current sensor according to embodiments of the present disclosure.

FIG. 9 shows a diagram of an exemplary resonator-based energy harvesting sub-system, according to embodiments of the present disclosure.

FIG. 10 shows a perspective view of an exemplary magnet-suspension assembly of a mechanical resonator and exemplary components of a piezoelectric transducer for a non-invasive, low-profile current sensor and/or energy harvester, according to embodiments of the present disclosure.

FIG. 11 shows a side view of the exemplary suspension assembly of FIG. 10 connected to a piezoelectric transducer for harvesting electrical energy from oscillation of the suspension assembly, according to embodiments of the present disclosure.

FIG. 12 shows an exemplary diagram of a cross-sectional view of components of a non-invasive, low-profile current sensor with a mechanical resonator having a magnet-suspension assembly, and an energy transducer(s), according to embodiments of the present disclosure.

FIG. 13 shows an exemplary failure diagram of von Mises stress versus Torsional Rotation (in degrees) related to the example suspension of the suspension assembly of FIGS. 10-11, according to embodiments of the present disclosure.

FIG. 14 shows an exemplary visual representation of von Mises stress (MPa) for the example suspension of the suspension assembly of FIGS. 10-11 undergoing torsional rotation, according to embodiments of the present disclosure.

FIG. 15 shows a perspective view of an exemplary suspension assembly with a portion of the magnet cut out to provide a better view of the components of the magnet-suspension assembly of a mechanical resonator as well as an energy transducer (e.g., electrodynamic coil of an electrodynamic transducer) for a non-invasive, low-profile current sensor and/or energy harvester, according to embodiments of the present disclosure.

FIG. 16 shows a top-side view of the exemplary suspension assembly of FIG. 15, according to embodiments of the present disclosure.

FIG. 17 shows a cross-sectional view of the exemplary suspension assembly of FIG. 15, according to embodiments of the present disclosure.

FIG. 18 shows a diagram of an exemplary first torsional mode of the suspension of the mechanical resonator for the non-invasive, low-profile current sensor and/or energy harvester of FIGS. 15-17, according to embodiments of the present disclosure.

FIGS. 19, 20, 21 and 22 illustrate different exemplary designs of a suspension for the magnet-suspension assembly of a mechanical resonator for the non-invasive, low-profile current sensor or energy harvester of FIGS. 15-17, according to embodiments of the present disclosure.

FIG. 23 shows an exemplary functional block diagram of a circuit protective device, such as a miniature circuit breaker, employing a non-invasive, low-profile current sensor and/or energy harvester, according to embodiments of the present disclosure.

FIG. 24 shows an exemplary energy monitoring subsystem using a PCB current trace sensor with a flexible connector for connecting to other electronic/electrical component(s), such as a signal conditioner and signal processing circuit(s), on another PCB substrate according to embodiments of the present disclosure.

FIG. 25 shows an example side view of an energy monitoring subsystem using a PCB current trace sensor with a flexible connector for connecting to other electronic/electrical component(s) on another PCB according to embodiments of the present disclosure.

### DETAILED DESCRIPTION OF EXAMPLE EMBODIMENTS

This description and the accompanying drawings illustrate exemplary embodiments of the present disclosure and should not be taken as limiting, with the claims defining the scope of the present disclosure, including equivalents. Various mechanical, compositional, structural, electrical, and operational changes may be made without departing from the scope of this description and the claims, including equivalents. In some instances, well-known structures and techniques have not been shown or described in detail so as not to obscure the disclosure. Further, elements and their associated aspects that are described in detail with reference to one embodiment may, whenever practical, be included in other embodiments in which they are not specifically shown or described. For example, if an element is described in detail with reference to one embodiment and is not described with reference to a second embodiment, the element may nevertheless be claimed as included in the second embodiment.

In accordance with various embodiments, systems and methods are provided for electrical-energy monitoring (such as current monitoring/sensing) and/or electrical-energy harvesting through a non-invasive, low-profile current sensor (or sensing device) and/or energy harvesting device or system (also referred herein as “energy harvester”), which can be provided as part of an integrated multifunctional energy system or subsystem. The energy monitoring can include monitoring current flowing through an electrical conductor (or electrical conductive path) in an electrical device or system, which can include one or more phases or poles. The non-invasive, low-profile current sensor can include a mechanical resonator and an energy transducer, which cooperate to provide energy-related measurements of the current flowing through the conductor, and if desired, also can harvest electrical energy for storage and/or to power an electrical component(s) or circuit(s), including those for the current sensor. The current sensor can include a mechanical resonator with a magnet-suspension assembly, which can oscillate due to time varying magnetic field from the current flowing (e.g., AC current) through the conductor. The magnet-suspension assembly can include a magnetodynamic volume, which can be a permanent magnet(s), magnetostrictive material(s) or a combination thereof. The energy transducer(s) can convert the oscillations of the magnet-suspension assembly to electrical energy proportional to the current flowing through the conductor. The electrical energy, in turn, can be used to provide an energy measurement (e.g., measurement of current, etc.) of the current flowing through the conductor, and/or harvested for storage or use thereof in powering an electrical component(s) or circuit(s).

In various embodiments, the energy transducer(s) can be an electrodynamic transducer, a piezoelectric transducer, electromechanical transducer, or other type or variation of transducer for converting mechanical energy, magnetic energy (or changes thereof) or other forms of energy produced from the oscillation of the magnet-suspension assembly (or component(s) thereof), or combination thereof.

Accordingly, the mechanical resonator can leverage the mechanical and electrical domains using electrodynamic coupling, e.g., interaction between an oscillating permanent magnet of the magnet-suspension assembly (due to time-varying magnetic field generated by current flowing through the conductor) and an energy transducer such as an electrodynamic transducer (e.g., coil(s)), piezo-electric transducer, or other suitable transduction or energy-conversion system A magnetic field generated by current flowing through an electrical conductor, which is parallel (or substantially parallel) and in proximity to the magnet-suspension assembly or component(s) thereof, can drive resonant oscillations of the magnet-suspension assembly.

The non-invasive, low-profile sensor/current sensor and/or energy harvester, which employ(s) a resonator-based system, is sometimes referred to herein as a “micro-resonator”, “microresonator”, “micro-resonator sensor”, “micro-resonator current sensor”, “micro-resonator energy harvester” or variations thereof such as for example when used in miniature circuit breaker or other similar circuit protective devices or other systems, with limited space for the installation of components therein. Such circuit protective or other systems also may be smart devices. As used herein, a “dual-transduction” or “dual-mode” micro-resonator can provide for both energy monitoring and/or energy harvesting using one or more energy transducers along with the mechanical resonator.

In other embodiments, in the systems and methods, the integrated multifunctional energy system can employ the mechanical resonator and one or more energy transducers to provide a non-invasive, low-profile energy harvester for energy harvesting and also can employ a non-invasive, low-profile PCB trace sensor for energy monitoring such as current monitoring or sensing. The energy harvester and the current sensor can be provided on the same substrate (e.g., PCB substrate) or on separate substrates (e.g., PCB substrates) which are connected across a flexible connector.

The non-invasive, low-profile current sensor, energy harvester, micro-resonator or integrated multifunctional energy system of the present disclosure can provide various features, benefits and/or advantages, including among other things, for example:
Non-Invasive proximity energy-related sensing;
Galvanic Isolation;
Housing-Less design;
Low-profile (e.g., thin, small, etc.) and inexpensive sensor (alternative to conventional sensors, such as current transformer (CT)) which allows for effective installation in specific and limited spaces, such as miniature circuit breakers and other similar circuit protective devices, or other space-limited systems that require monitoring of electrical energy;
Availability of a wider range of advanced functions/capabilities as the sensor or micro-resonator can offer energy harvesting as well as current monitoring in a dramatically reduced size;
A low-profile device with a thickness of approximately 1.6 mm, and/or a volume of approximately 0.2 cm³ (versus 1.5 cm³ for a 13-turn CT);
Integrated hardware or module (e.g., signal conditioning circuit and/or other circuits may be included) architecture solution that can be placed on or in relation to terminals (e.g., L1/L2), bus bars, and bonding wires, Wiring Devices, among others;
Hardware solution intended to mitigate manufacturing/assembly complexity (sensor+flexible current path);
Self-powered current sensor feature: energy harvesting functionality to power advanced functions, actuators, and other electrical components or circuits;
Hardware architecture solution that affords for easy assembly on traditional/conventional plastic bases, covers, or housing (e.g., plastic MCB bases, covers, or housing);
PCB sensor and/or energy harvesting benefits (e.g., better manufacturing control from PCB technologies); and/or
Cost savings on the manufacturing line by independent energy monitoring screening (e.g., Standalone testing possibility—may not need to assemble the final current path to test/validate the sensor system).

Furthermore, an advantage of a micro-resonator based on a meander/meandering suspension is that they can have spring constants that are linear over a relatively large displacement and are less sensitive to residual stress than straight-beam fixed-fixed suspensions.

In various embodiments, a dual-transducer micro-resonator can be used to harvest energy and to perform current monitoring. When a power line loss occurs, energy harvesting can be done by using alternate energy transducers that are not dependent on electrical current magnetic fields, such as thermo-magnetic transducers with the proper setup.

These and other example systems and methods or other features and benefits of the present disclosure are shown and/or described below and in the attached figures and Appendices (which are incorporated herein in their entirety).

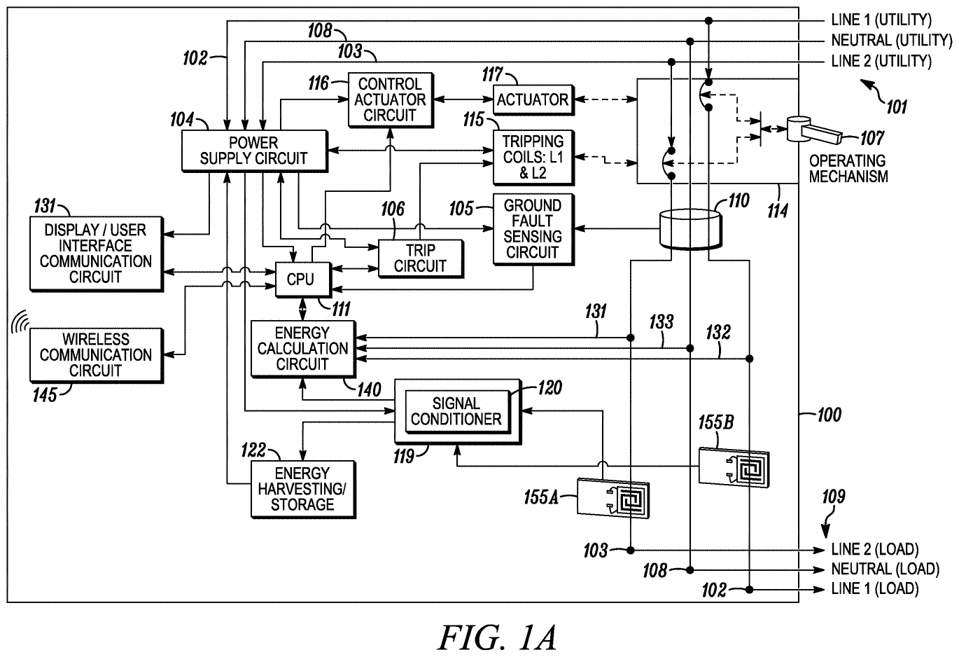

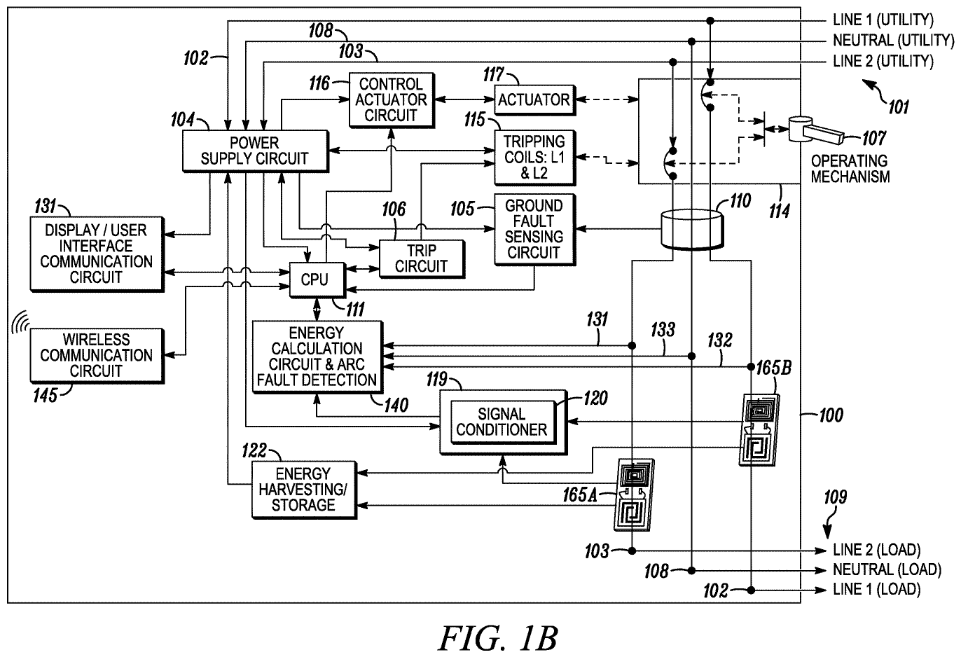

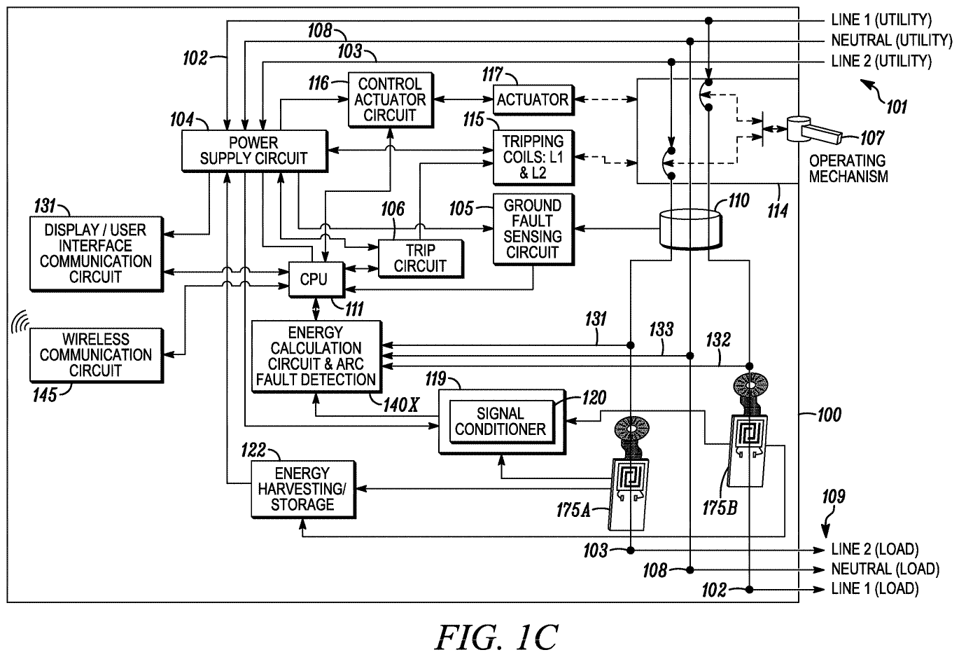

Referring now to FIG. 1A, a schematic diagram is shown for an exemplary current flow monitoring device 100 that can use one or more integrated multifunctional energy systems (or subsystems), which can implement functions including but not limited to monitoring energy (e.g., current, voltage, etc.) flowing through one or more conductors and/or harvesting energy due to electrical energy flowing through one or more electrical conductors, as well as other functions including signal processing and so forth. In this example, the integrated energy system can employ a resonator such as a micro-resonator and at least one energy transducer in order to provide a non-invasive, low-profile current sensor (also referred to as a “current sensing device”) and/or energy harvester according to an embodiment of the present disclosure. The current flow monitoring device 100 in this example is a 2-pole electronic circuit breaker that is designed to monitor current flow and interrupt the flow upon occurrence of a fault condition, and can be a smart device. To this end, the breaker 100 includes a number of functional components or modules, some of which are represented here as blocks. It will be understood, of course, that each block shown here (and in subsequent figures) may be divided into several constituent blocks, or two or more blocks may be combined into a single block, within the scope of the present disclosure. For the purposes of discussion, the reference number 100 will be generally used herein to reference a current flow monitoring device (or types thereof), which may vary in function, operation and component(s), in accordance with various embodiments described herein.

As can be seen, the breaker 100 can receive utility lines or conductors 101, such as a first power line L1 or Line 1, a second power line L2 or Line 2 and a neutral conductor N or NEUTRAL connected to the line side (or its line-side connectors) of the breaker 100. Current from the utility power lines L1 and L2 are carried over main conductors 102 and 103 respectively to various loads connected to the load side (or its load-side connectors) of the breaker 100. A neutral conductor 108 connects the load neutrals to the utility neutral conductor. As shown, the breaker 100 outputs the signals received from lines L1, L2 and Neutral to corresponding load-side lines or conductors 109. The breaker 100 in this example includes a ground fault sensing circuit 105 connected to a ground fault sensor 110. The main conductors 102 and 103 pass through the ground fault sensor 110 and also pass in proximity and in parallel (or substantially parallel) to respective micro-resonators of current sensors and/or energy harvesters of the integrated energy systems 155A and 155B. An integrator or other signal processing front end 119, which may include a signal conditioner 120, receives the signals from the current sensors and/or energy harvesters of the integrated energy systems 155A and 155B and provides the signals to an energy calculation (or measurement) and arc fault detection circuit(s) 140 and an energy harvesting storage 122, respectively. Power for the energy calculation/measurement and arc fault detection circuit(s) 140, CPU 111, and other components in the breaker 100 is provided by a power supply circuit 104, as shown. The power supply circuit 104 can receive power from an upstream power source (e.g., the utility) and/or the energy harvesting storage 122.

Operation of the breaker 100 is generally well known in the art and therefore only described briefly here. In general, the CPU 111, which may be a microcontroller, monitors current sample measurements obtained from the ground fault sensor 110 to detect occurrence of a fault condition in a known manner. Upon detection of a fault condition, the CPU 111 outputs a trip signal to a trip circuit 106 that actuales tripping coil(s) 115, which in turn opens a trip mechanism 114 (e.g., switch(es), relay(s), contact(s), etc.) to interrupt current flow through the breaker 100. A reset mechanism 107 allows a user to later set/reset the trip mechanism/switch 114 after a trip event. Energy and power usage is measured by the energy calculation circuit of the circuit(s) 140 using line voltages 131 and 132, neutral voltage 133, and current signal supplied by the signal processing front end 119. Arc fault detection is performed by the arc fault detection circuit of the circuit(s) 140 for the monitored lines or conductors 102, 103 associated with Lines 1, 2 respectively. A wireless communication circuit 145 (or wireline communication circuit) may be used to transmit trip data, current sample measurements, energy measurements, and other information to an external monitoring system, such as a power usage monitoring system, for analysis. A display communication circuit 131 may be used to transmit trip data, current sample measurements, energy measurements, and other information to a display for display or output thereof. Furthermore, the CPU 111 may be configured to control the operation of the trip mechanism/switch 114, via control actuator circuit 116 and actuator 117, to selectively turn ON or OFF (or interrupt) current flow to the circuit and load(s) connected thereto downstream of the breaker 100, under certain conditions. For example, the CPU 111 may turn ON or OFF the flow of current on the main conductors according to commands received from a remote device via wireless communication circuit 107 or the detection of certain conditions at the breaker 100. The remote device may be part of a home automation system for regulating energy or power usage/consumption (e.g., turn ON or OFF according to schedule, or when energy usage satisfies or exceeds (or not) a predefined threshold, or when other conditions are detected).

In this example embodiment, the breaker 100 employs two integrated multifunctional energy systems 155A and 155B, each of which includes a non-invasive, low-profile sensor for monitoring energy flowing through a conductor (e.g., current, voltage, etc.) and a low-profile energy harvester for harvesting energy due to energy flow through the conductor. In various embodiments, each of the integrated multifunctional energy systems 155A and 155B also can incorporate the signal processing front end 119 with the signal conditioner 120, and/or embedded connectors for connecting components, on a PCB substrate. The current sensor and/or energy harvester of each integrated energy system 155A, 155B can be implemented through a micro-resonator and one or more energy transducers, which are provided on a PCB substrate. For example, each of the integrated energy systems 155A and 155B can include a mechanical resonator (with a magnet-suspension assembly) and one or more energy transducers (e.g., coils, piezoelectric element, etc.), which are integrated on a PCB substrate. As shown, unlike conventional sensors such as CT sensors, the current sensor and/or energy harvester (or components thereof) of each energy system 155A or 155B is placed in proximity and in parallel (or substantially parallel) with a respective line conductor 103 or 102 (or a portion thereof (or vice-a-versa) respectively, and thus, can perform monitoring and/or energy harvesting in a non-invasive manner with respect to a respective conductor.

The non-invasive, micro-resonator current sensor and/or energy harvester can provide several advantages over conventional current sensors, including a reduced volume, small footprint, low-profile, simple hardware architecture, easier assembly and installation, and is relatively inexpensive to manufacture compared to conventional current transformers. As an example, the non-invasive, micro-resonator sensor and/or energy harvester as described herein can be designed to have a size of approximately 0.2 cm³ in comparison to a size of 1.5 cm³ for a 13-turn CT. Furthermore, the integration of the signal processing front-end 119 (including the signal conditioner 120) and the current sensor(s) along with other associated components (e.g., wiring, etc.) including embedded connectors (for connecting the components) into the PCB substrate can provide additional advantages over conventional designs, including improved installation and assembly of components for current flow monitoring and/or energy harvesting device; and other benefits as described herein.

In some embodiments, each micro-resonator current sensor and/or energy harvester can be provided on a PCB substrate as an integrated PCB sensor and/or energy harvester module which can also include a signal processing front end 119 with signal conditioner 120 on the PCB substrate, and other electrical component(s) or circuit(s). The integrated PCB sensor and/or energy harvester module can be a non-invasive, low-profile current sensor and/or energy harvester, which can allow for greater flexibility in the installation thereof in devices, such as miniature circuit breakers, with limited space. In various embodiments, the integrated PCB sensor and/or energy harvester module can be placed or mounted in areas (which may be unsuitable for installation of conventional sensors such as CT), such as on or in relation to a lug terminal, breaker base, or other locations, to perform current sensing and/or energy harvesting in the circuit breaker.

The flow monitoring device 100 of FIG. 1A is provided as an example. It should be understood that the flow monitoring device 100 of FIG. 1A can employ different types of PCB modules with different types of micro-resonator sensor(s) (e.g., single-mode/transduction sensor, dual-mode/transduction sensor, etc.) and different or additional types of components on the PCB substrate which may implement a variety of functionality. For example, the breaker 100 can be a smart miniature circuit breaker with dual-function integrated energy solution for both current sensing and energy harvesting. The flow monitoring device 100 of FIG. 1A also can include different components and features depending on the type of flow monitoring device (e.g., circuit breaker, wiring device, metering device, an arc fault circuit interrupt (AFCI) device, a ground fault interrupt (GFI) receptacle wiring device, a GFI smart plug, etc.), which also may take the form of a smart device. Additional example embodiments are provided in the schematic diagrams of FIGS. 1B and 1C.

FIG. 1B is a schematic diagram for an exemplary current flow monitoring device 100 that uses one or more integrated multifunctional energy systems according to an embodiment of the present disclosure. The current flow monitoring device 100 of FIG. 1B is basically the same as the monitoring device of FIG. 1A, except that the integrated multifunctional energy systems 165A and 165B of FIG. 1B employs a micro-resonator and an energy transducer to provide an energy harvester for harvesting energy from an electrical conductor and a PCB trace sensor to perform energy monitoring (e.g., current sensing, voltage sensing, etc.) of the electrical conductor. In this example, each integrated multifunctional energy system can be provided through a PCB module which integrates the PCB trace sensor (e.g., current sensor, etc.), the energy harvester, and embedded connectors as well as, if desired, the signal processing front-end (including signal conditioner) and/or the energy calculation/measurement circuit to provide an energy monitoring and harvesting board. For example, as shown in FIG. 1, the monitoring device 100 can include energy systems 165A and 165B, each of which can take the form of a PCB module having various components on a PCB substrate, such as trace current sensor(s), micro-resonator and energy transducer(s), embedded connectors for connecting the components of the PCB module as well as other components such as the signal processing front-end 119 with a signal conditioner 120, energy calculation/measurement and arc fault detection circuit(s) 140, and components to provide other functionality as desired.

FIG. 1C shows a schematic diagram illustrating an exemplary current flow monitoring device 100 that uses an integrated multifunctional energy system 175A, 175B for monitoring energy flow (e.g., current) through an electrical conductor and harvesting energy from the energy flow through the electrical conductor. Each integrated energy system 175A, 175B can include a low-profile current sensor PCB module with a PCB trace current sensor, which is connected to other PCB section/substrate (with electronic/electrical components including an energy harvester) across a flexible connector, according to yet another embodiment of the present disclosure. The energy harvester can be implemented using a resonator and energy transducer(s), such as for example described herein. The current flow monitoring device 100 of FIG. 1C is basically the same as the monitoring device of FIG. 1B, except that the monitoring device of FIG. 1C provides the PCB trace sensor and the energy harvester on different PCB sections/substrates which are connected across a flexible connector. The PCB trace sensor of the integrated energy system 175A, 175B also may have a different configuration, e.g., a conductive trace design which extends radially outward from a hole (on a PCB section/substrate) through which a portion of the electrical conductor to be monitored is received.

For example, in the integrated multifunctional energy system 175A, 175B, the PCB trace sensor is connected to other PCB section/substrate with electronic/electrical components such as the energy harvester, across a flexible connector which can enable transmission of electrical signals between components of the PCB sections/substrates. The electronic/electrical components of the other PCB section substrate also can include signal conditioning circuit, signal processing circuit, and/or other electronic/electrical components. The signal conditioning circuit can include a signal processing front-end (e.g., 119) with a signal conditioner (e.g., 120), which can include an integrator, amplifier(s), filter(s) and/or other electrical components. The signal processing circuit can include an energy calculation circuit and an arc fault detection circuit, as shown by block 140. In this example embodiment, the PCB module with the PCB trace sensor and the flexible connector, also can be separately tested, easily assembled and installed into the current flow monitoring device 100, easily removed from the current flow monitoring device 100, and/or retro-fitted into existing current flow monitoring devices.

The flow monitoring device 100 of FIG. 1C is provided as an example. It should be understood that the integrated energy system 175A, 175B of the flow monitoring device 100 of FIG. 1C can employ different numbers and types of PCB sub-modules with different types of trace current sensor(s) and different combinations of electronic/electrical components on the PCB substrates to implement different or additional functionality including energy harvesting, signal processing, energy storage, and so forth. The integrated energy system 175A, 175B also can include different components and features depending on the type of flow monitoring device (e.g., circuit breaker, wiring device, metering device, etc.), which can take the form of a smart device. In the integrated energy system 175A, 175B, the PCB trace sensor also can have a varied design, such as a different overall size and shape, different opening shape (e.g., a notch, etc.) and so forth.

Furthermore, in this example, the current flow monitoring device is a 2-pole device. In general, in multi-pole devices with multiple conductors to monitor, such devices can employ a plurality of integrated multifunctional energy systems each with a single PCB current trace sensor connected to a respective separate PCB substrate (having electronic/electrical components including an energy harvester) across a flexible connector, or can employ an integrated multifunctional energy system with a plurality of PCB current trace sensors connected to a separate PCB substrate (having electronic/electrical components including one or more energy harvesters) across respective flexible connectors.

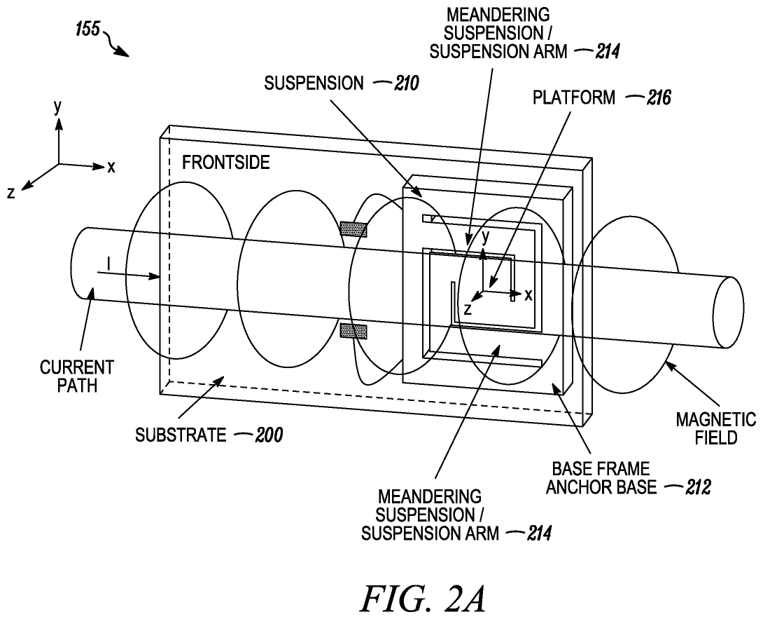

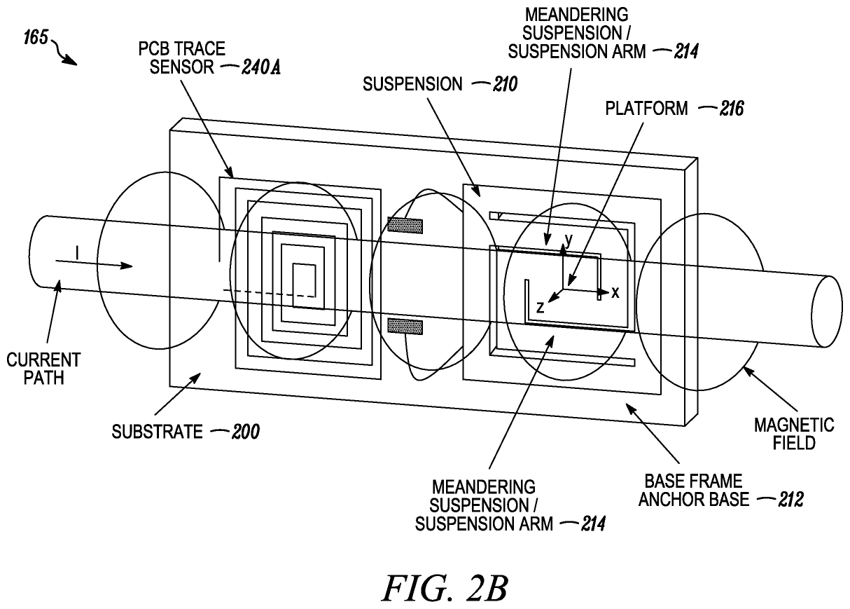

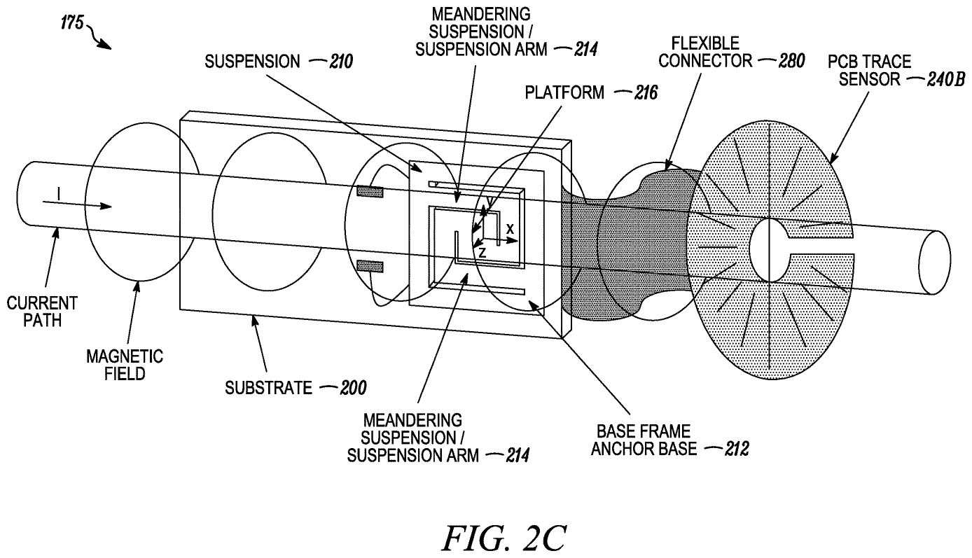

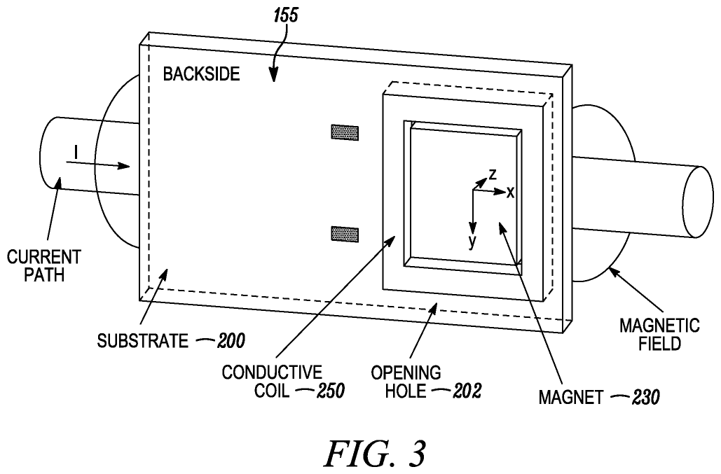

FIGS. 2A and 3 show diagrams of respective front side and back side of an exemplary multifunctional energy system (or subsystem) 155 for sensing current flow through a conductor and harvesting energy from the current flow through the conductor, according to embodiments of the present disclosure. The integrated energy system 155 is an example of the integrated energy system 155A, 155B of FIG. 1A, and can include a mechanical resonator and one or more an energy transducers on a PCB substrate. In this example, the mechanical resonator includes a magnet-suspension assembly, which has a suspension 210 and a magnetodynamic volume 230, connected to the suspension 210. The magnetodynamic volume can be formed of a permanent magnet(s), a magnetostrictive material(s) or a combination thereof.

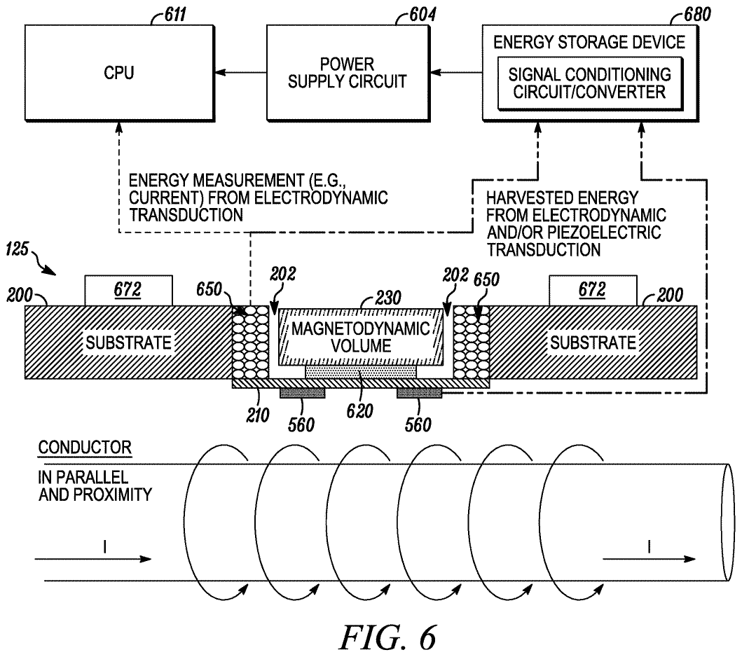

As shown in FIGS. 2A and 3, the suspension 210 can include a base frame 212 (e.g., mounting frame or anchor base), a platform 216 and suspension element(s) 214 connected on one end to the base frame 212 and another end to the platform 216. The suspension element(s) 214 can be a suspension arm, beam, segment or element, such as a meandering suspension arm, beam, segment or element. In this example, the suspension 210 has two suspension arms, beams, segments or elements 214 which are meandering (or have a meandering design), and the platform 216 is a central (or centrally located) platform relative to the suspension 210 or the magnet-suspension assembly or component(s) thereof. The magnetodynamic volume 230 is connected to the platform 216 of the suspension 210. The magnetodynamic volume 230 can be connected to the platform 216, across a spacer (e.g., 620 of FIG. 6).

As further shown in FIGS. 2A and 3, the integrated energy system 155 can include a first energy transducer such as a conductive coil(s) 250. The conductive coil 250 is a conductive coil(s), which is located or placed around and in proximity to at least a portion of the magnetodynamic volume 230. The component of the magnet-suspension assembly, such as the suspension 210, base frame 212, suspension elements 214 and platform 216, as well as the coil 250 are arranged or mounted in an opening 202 of a substrate 200. The opening 202 can be an opening, hole or through-hole, a cavity, chamber or other type of open region in the substrate 200, within which one or more or at least a portion of the component(s) of the magnet-suspension assembly of the resonator and/or the coil 250 of the energy transducer are mounted. The substrate 200 can be a printed circuit board (PCB) substrate. In this example, the coil 250 can extend around an interior wall of the opening 202, which has a square or rectangular shape. The mechanical resonator and energy transducer(s), as described herein, can be integrated into or onto the substrate 200, such as a PCB substrate, to provide a non-invasive, low-profile integrated PCB micro-resonator module or package for current sensing and/or energy harvesting. The integrated PCB sensor module can also incorporate other component(s), circuit(s) and functionality, which can also be integrated into or onto the substrate 200, including, for example, the signal processing front end including the signal conditioner, signal chain circuit(s), contact(s) and so forth.

In various embodiments, the coil 250 may also be a printed circuit board (PCB) coil, which is made up of traces that create a coil on a substrate. The substrate for the coil may be a second PCB section connected to a flexible region, or may be the same PCB substrate on which the micro-resonator is installed.

In various embodiments, at least one integrated energy system 155 or component(s) thereof can be installed, provided, positioned, arranged and/or mounted in proximity and in parallel (or substantially parallel) to an electrical conductor, such as for example, a line conductor to be monitored in a circuit breaker or circuit protective device, which can take the form of a smart device. In this example, the integrated energy system 155 is positioned or installed with the conductor or a portion thereof being located adjacent and in proximity to a front side of the substrate 200 across from an outer surface of the suspension 210. However, it should be understood that, in other embodiments, the conductor can be located adjacent and in proximity to a back side of the substrate 200 across from an outer surface of the magnetodynamic volume 230.

In an example operation, the integrated energy system 155 can monitor or sense the current (I) flowing through the conductor using the first energy transducer, e.g., coil 250. For example, the magnet-suspension assembly of the resonator oscillates under influence of a time-varying magnetic field generated by the flow of current through the conductor which is arranged in proximity and in parallel (or substantially parallel) to the magnet-suspension assembly or component(s) thereof, such as for example the magnetodynamic volume 230. An electromagnetic force (EMF) is induced on or through the coil(s) 250 of the first energy transducer by the oscillations of the permanent magnet(s) to generate electrical energy to produce an output voltage or current that is proportional to the current flowing through the conductor. The proportional output electrical signal (e.g., voltage or current) can provide a measurement of the current flowing through the conductor, and can be further processed, if desired, to determine, compute or derive other electrical parameters or characteristics (e.g., power, etc.) about the conductor using the current measurement.

Furthermore, in various embodiments, the electrical energy from the coil 250 can also be harvested for storage in an energy storage device (e.g. rechargeable battery, capacitor(s), etc.) for further usage and/or used to power one or more component(s) or circuit(s) on the current sensor (e.g., signal conditioner, etc.) or in a circuit protective device (e.g., the CPU and other components of the device 100 in FIG. 1A, 1B or 1C). In various embodiments, the harvested and stored energy also can be used to power component(s) on a smart device (e.g., a smart circuit breaker, etc.) to perform important or critical functions, such as for example writing critical data after a power loss, notifying users about the condition of their smart gadget in the event of a power outage (e.g., via communication circuit), performing critical actions mandated right before a power interruption occurs, and so forth. In other embodiments, a second energy transducer or other energy transducers can be employed, along with the mechanical resonator of the current sensor, for energy harvesting. The second energy transducer can, for example, be an electromechanical transducer, a piezoelectric transducer, or a magneto-electric transducer.

In various embodiments, another energy transducer(s) (e.g., a third energy transducer) can also be added to allow for current monitoring. The third energy transducer can be a planar coil current sensor, which can be aimed at capturing more signals in the frequency spectrum. For example, the third energy transducer can be used to capture current signals in frequency range(s), which may not be captured or adequately captured by the resonator-based current sensor. For example, the resonator-based current sensor can be used to measure current flow through a conductor in a first frequency range, and the third energy transducer or planar coil current sensor can be used to measure current flow through the conductor in a second frequency range which differs from the first frequency range. In some embodiments, one of the resonator-based current senor and the third energy transducer can be used to capture low/lower frequency signals and the other of the resonator-based current senor and the third energy transducer can be used to capture/monitor high/higher frequency signals. The planar coil current sensor can be a PCB trace sensor, which is provided on the same substrate (e.g., 200) as the resonator. An example of a planar coil current sensor (e.g., 240A) is shown and described below in the embodiment of FIG. 2B. The signals captured by the third energy transducer or additional energy transducer(s) can be used, individually or along with other monitored current signals from other current sensor(s), to detect for fault or other conditions on the conductor or electrical system (e.g., arc fault, etc.), or to perform other monitoring functions or operations.

FIG. 2B shows diagram of a front side of an integrated multifunctional energy system 165 for performing current sensing and energy harvesting in relation to current flow through an electrical conductor, according to embodiments of the present disclosure. The integrated energy system of 165 is an example of the integrated energy system 165A, 165B of FIG. 1B, and can include basically the same or similar components of the integrated energy system of 155 in FIGS. 2A and 3 (including the resonator and energy transducer(s)), except that the integrated energy system 165 in FIG. 2B can also include a PCB trace sensor 240A on the substrate 200. The PCB trace sensor 240A can be used as a current sensor to monitor current flow through an electrical conductor and the resonator and transducer(s) can be used as an energy harvester to harvest energy due to current flow through the electrical conductor. The trace sensor 240A can take the form a conductive trace, which is designed with size and shape to produce a proportional output electrical signal corresponding to the current flow through the electrical conductor. The PCB substrate 200 can be positioned in the current monitoring device (e.g., 100) with a portion(s) of the conductor to be monitored in proximity and in parallel (or substantially parallel) to PCB trace sensor 240A and the component(s) of the resonator (e.g., the suspension assembly or its component(s)).

In this example, the conductive trace is designed with a spiral or winding shape (e.g., a rectangular/square spiral or winding shape) on the substrate 200 or a component(s) connected on the substrate 200 to provide a planar coil current sensor; however, it should be understood that any suitable trace design (e.g., shape, dimension, size, location, etc.) may be employed to provide for a proportional output electrical signal corresponding to current flow through an electrical conductor to be monitored, based on the application. For example, in other embodiments, the trace design for the planar coil current sensor can take the form of a triangular or circular spiral or winding. The electrically conductive trace may be formed on a top or bottom surface of a PCB substrate, or it may be formed within the PCB substrate on an internal layer of the PCB substrate. In some embodiments, multiple electrically conductive traces may be used to form multiple planar coils. Each coil may occupy a separate layer in the PCB substrate, or two a more coils may occupy the same layer in the PCB substrate in an interleaved fashion.

Lead terminals can be provided on the PCB substrate for each planar coil, for example, using vias to connect each planar coil to its respective lead terminals. The lead terminals are provided to allow the planar coil current sensor to be electrically connected to other components on the substrate or within the breaker, such as an integrator or other signal processing front end. The lead terminals may take any suitable form, with one of the lead terminals implemented by routing a trace from an interior end of the planar coil internally through the PCB substrate (e.g., 200) near to or adjacent the other lead terminal by means of vias (not expressly labeled).

An operational example of energy harvesting by the resonator and energy transducer(s) due to current flow on an electrical conductor has been described above with reference to FIGS. 2A and 3. As for the PCB trace sensor 240A, during operation, an electromagnetic force (EMF) is induced on or through the conductive trace of the PCB trace sensor 240A by the magnetic field generated by the current flow through the conductor (e.g., line conductor L1 or L2) to generate electrical energy to produce an output voltage or current that is proportional to the current flowing through the conductor. The proportional output electrical signal (e.g., voltage or current) can provide a measurement of the current flowing through the conductor, and can be further processed, if desired, to determine, compute or derive other electrical parameters or characteristics (e.g., power, etc.) about the conductor using the current measurement.

In various embodiments, the integrated multifunctional energy system also can include additional energy transducer(s) in relation to the resonator for additional current monitoring and/or additional energy harvesting. The additional current monitoring can monitor the same or different frequency ranges as the PCB trace sensor 240A.

FIG. 2C shows diagram of a front side of an integrated multifunctional energy system 175 for performing current sensing and energy harvesting in relation to current flow through an electrical conductor, according to embodiments of the present disclosure. The integrated energy system of 175 is an example of the integrated energy system 175A, 175B of FIG. 1C, and can include basically the same or similar components of the integrated energy system of 155 in FIGS. 2A and 3 (including the resonator and energy transducer(s)), except that the integrated energy system 165 in FIG. 2B can also include a PCB trace sensor 240B on a separate PCB module, which is connected to the PCB module with the substrate 200 across a flexible connector 280.

The flexible connector 280 can be a flat, flexible connector, which can physically, electrically and/or communicatively link two separate PCB sections/substrates (or components thereof), and can provide for one or more communication pathways (e.g., communication lines) to enable communication of signals/data between the connected PCB sections/substrates, e.g., from the PCB trace sensor(s) to another PCB section(s)/substrate(s). These communicated signals can, for example, include energy-related measurements (e.g., current or voltage) by the PCB trace sensor of energy signals on a conductor (e.g., a line conductor or other conductor) of the current flow monitoring device. The dimension of the flexible connector and PCB sections/substrates, including their size and shape, can be designed according to the space-limitations associated with the application. In various embodiments, the flexible connector can be a flexible flat cable (FFC), ribbon-type cable, or other suitable cable connector for use with printed circuit boards.

The PCB trace sensor 240B can be used as a current sensor to monitor current flow through an electrical conductor and the resonator and transducer(s) can be used as an energy harvester to harvest energy due to current flow through the electrical conductor. The trace sensor 240B can take the form a conductive trace, which is designed with size and shape to produce a proportional output electrical signal corresponding to the current flow through the electrical conductor. In this example, the conductive trace is designed around an opening of a PCB substrate to extend radially outward (e.g., Rogowski-like PCB trace current sensor); however, it should be understood that any suitable trace design may be employed on a suitable substrate (e.g., PCB substrate) to provide for a proportional output electrical signal corresponding to the current flow through an electrical conductor to be monitored, based on the application. The PCB substrate 200 can be positioned in the current monitoring device (e.g., 100) with a portion of the conductor to be monitored in proximity and in parallel (or substantially parallel) to the component(s) of the resonator (e.g., the suspension assembly or its component(s)), and another portion of the conductor to be monitored being positioned through the opening of the PCB trace sensor, which is on another PCB section or substrate.

An operational example of energy harvesting by the resonator and energy transducer(s) from current flow on an electrical conductor has been described above with reference to FIGS. 2A and 3. As for the PCB trace sensor 240B, during operation, an electromagnetic force (EMF) is induced on or through the conductive trace of the PCB trace sensor 240B by the magnetic field generated by the current flow through the conductor (e.g., line conductor L1 or L2) to generate electrical energy to produce an output voltage or current that is proportional to the current flowing through the conductor. The proportional output electrical signal (e.g., voltage or current) can provide a measurement of the current flowing through the conductor, and can be further processed, if desired, to determine, compute or derive other electrical parameters or characteristics (e.g., power, etc.) about the conductor using the current measurement.

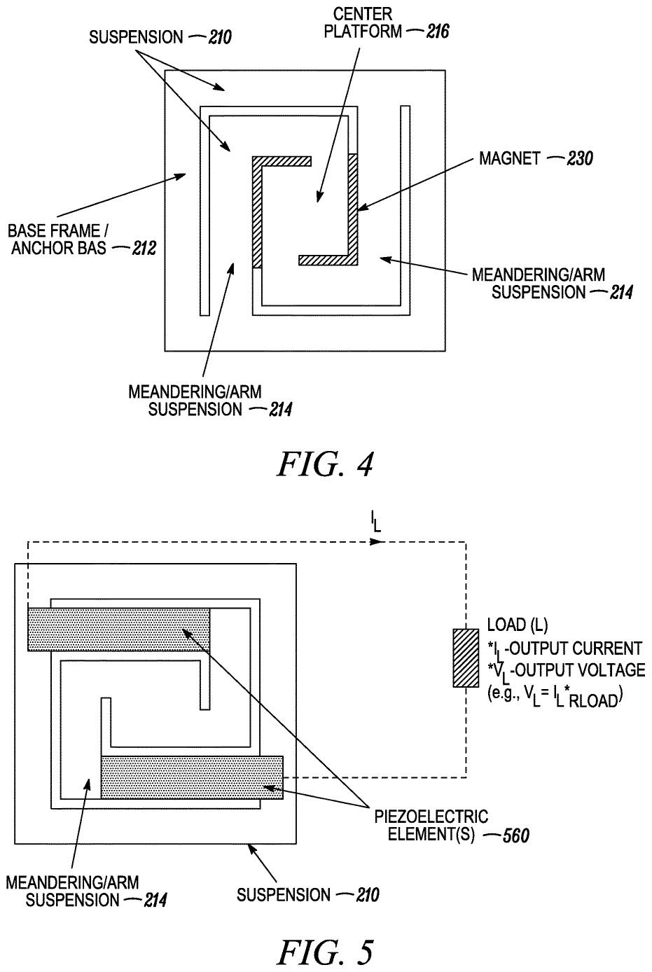

FIG. 4 shows an exemplary diagram of the suspension 210 of a magnet-suspension assembly of a mechanical resonator for a non-invasive, low-profile current sensor, according to embodiments of the present disclosure. As shown, the suspension 210 can include the base frame 212, suspension element(s) 214, and platform 216. In this example, the suspension element(s) 214 includes two meandering suspensions (or suspension arms, beams, segments or elements), each of which are connected between the platform 216 and the base frame 212. The platform 216 is a central (or centrally located) platform. As generally shown through the slots/openings of the suspension 210, the magnetodynamic volume 230 can be connected to the center platform 216, such as across a spacer. The design of the suspension element(s) 214 and the platform 216 are symmetrical or generally symmetrical. The suspension 210 and its components can be formed as a single or unitary piece or component, or alternatively, can be formed of a plurality of separate pieces or components, which are connected together. The components of the suspension 210 can be made of the same material, or different materials.

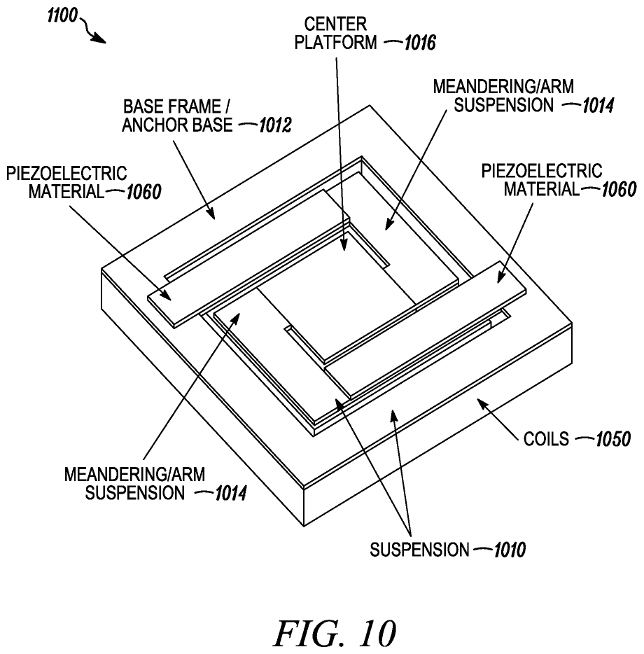

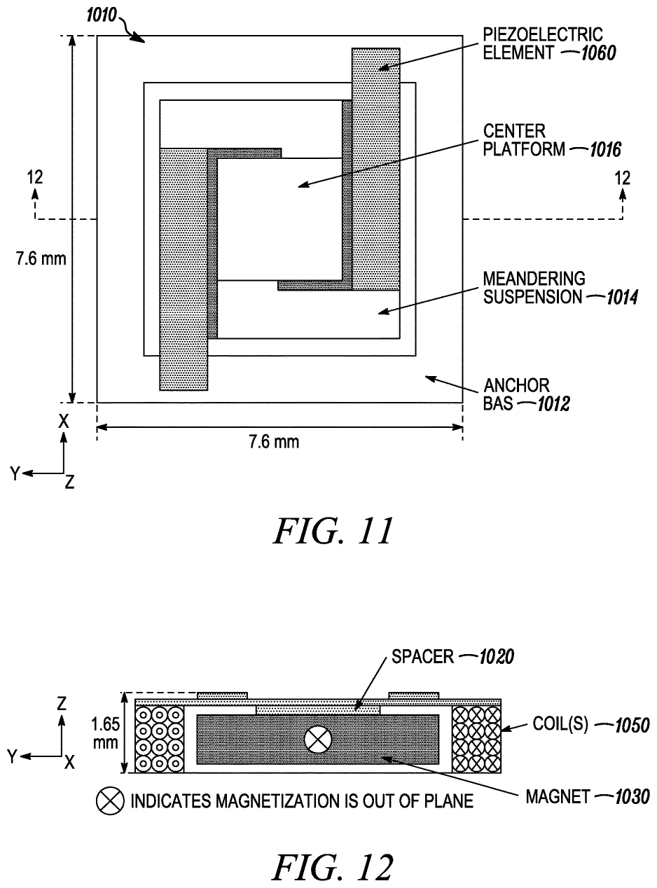

FIG. 5 shows an exemplary diagram of the suspension 210 of a suspension assembly of FIG. 4, which is connected to a piezoelectric transducer for harvesting electrical energy from oscillation of the magnet-suspension assembly, according to embodiments of the present disclosure. In this example, a second energy transducer, such as the piezoelectric transducer, is employed, along with the mechanical resonator of the current sensor, to harvest electrical energy from the oscillations of the magnet-suspension assembly of the mechanical resonator. The piezoelectric transducer can include two piezoelectric elements 560, such as arms, segments or other elements, are connected to the suspension 210. Specifically, each piezoelectric element 560 is connected to a respective meandering suspension element 214, and is also electrically connected in series to each other. As shown, the piezoelectric elements 560 can generate electrical energy through the piezoelectric effect as a result of mechanical stress applied thereto from vibrations produced by oscillation of the suspension 210 or component(s) thereof. The amount of electrical energy generated is proportional to the mechanical stress applied to the piezoelectric elements 560. The electrical energy generated from the piezoelectric transducer, e.g., in the form of a current I_{L}, can be harvested and stored in an energy storage device or system, such as a rechargeable battery, capacitor(s), etc. A more detailed example of such a dual-transduction or -mode sensor configuration (including a discussion about mechanical stress) are provided further below with reference to the example embodiments of FIGS. 10-12.

FIG. 6 shows an exemplary diagram of a cross-sectional view of components of a non-invasive, low-profile current sensor with a mechanical resonator having a magnet-suspension assembly, and two energy transducers, according to embodiments of the present disclosure. In this example, the current sensor is an integrated PCB sensor module or package, in which sensor components for electrical-energy monitoring and electrical-energy harvesting, along with other electrical component(s) and circuit(s), as shown by reference generally to elements 672, are integrated into/onto a substrate 200, such as a PCB substrate. The elements 672 can include the signal processing front end including the signal conditioner, signal chain circuit(s), contact(s) and/or other circuits.

As shown, the magnet-suspension assembly of the mechanical resonator and the coil(s) 650 are connected (e.g., connected, mounted, attached, etc.) in the opening 202 of the substrate 200, with the magnetodynamic 230 or a portion thereof connected in proximity to the coil 650 of a first energy transducer. The magnetodynamic volume 230 can be formed of a permanent magnet(s), a magnetostrictive material(s) or a combination thereof. The coil 650 can be connected, directly or indirectly, to and around the interior walls defining the opening 202 of the substrate 200. The magnetodynamic volume 230 can be wholly or partially positioned in the opening 202, with the coil(s) positioned in proximity around the magnetodynamic volume 230 or a portion thereof (e.g., the coil 650 surrounds the magnetodynamic volume 230 or portion thereof).

The magnet-suspension assembly of the mechanical resonator can include the suspension 210, magnetodynamic volume 230, and spacer 620 that is connected between the suspension 210 and the magnetodynamic volume 230. The suspension 210 and its components can be made of titanium or titanium alloy, aluminum or aluminum alloy, or a non-magnetic alloy. The spacer can be made of silicon, and formed as a silicon wafer. The spacer 620 can be design with a smaller profile than the magnetodynamic volume 230 and/or the platform (e.g., 216 in FIG. 4) of the suspension 210. The magnetodynamic volume 230 can be a permanent magnet(s), magnetostrictive material(s) or other suitable magnet or magnetically charged structure, which can be formed of a suitable magnetic material or alloy. The sensor 125 can monitor the current flowing through the conductor, and provide a current measurement or determine, compute or derive other energy-related measurements based on the current measurement. The spacer 620 may be formed on the platform of the suspension 210 or connected to the platform using an adhesive or other suitable connection techniques. The magnetodynamic volume 230 can be connected to the platform of the suspension 210 using an adhesive or other suitable connection techniques.

As further shown, the current sensor 125 can include, if desired, a second energy transducer, such as piezoelectric transducer which can employ two piezoelectric elements 560 that are connected to the suspension 210 or a component there(of) and that are electrically connected in series (e.g., example in FIG. 5).

As previously explained, in operation, the magnet-suspension assembly oscillates due to the time varying magnetic field generated by the current flow I through the conductor. An electromagnetic force (EMF) is induced on or through the coil 650 of the first energy transducer by the oscillations of the magnetodynamic volume 230 to generate electrical energy to produce an output voltage or current that is proportional to the current flowing through the conductor. The proportional output electrical signal (e.g., voltage or current) can provide a measurement of the current flowing through the conductor, which can be provided to a CPU 611 of the breaker, such as for example in FIG. 1 (e.g., CPU 111). Furthermore, electrical energy also can be generated from the second energy transducer, e.g., the piezoelectric transducer, through the piezoelectric effect from the mechanical stress applied to the piezoelectric elements 560 from the vibrations produced by oscillation of the suspension 210 or component(s) thereof. In various embodiments, the electrical energy generated by the first energy transducer (e.g., coil(s) 650) and/or the second energy transducer (e.g., piezoelectric elements 560) can be harvested and stored, after signal conditioning and conversion (e.g., AC to DC conversion, etc.), for storage in an energy storage device 680.

In various embodiments, the magnetodynamic volume 230 can be formed of a magnetostrictive material. In operation, the fluctuating current magnetic field of current flow through an electrical conductor causes mechanical stress on the resonator, which will result in mechanical stress on the suspension. Electrical power can be extracted/harvested from the resulting mechanical stress on the suspension through the use of an energy transducer(s), such as piezoelectric patches.

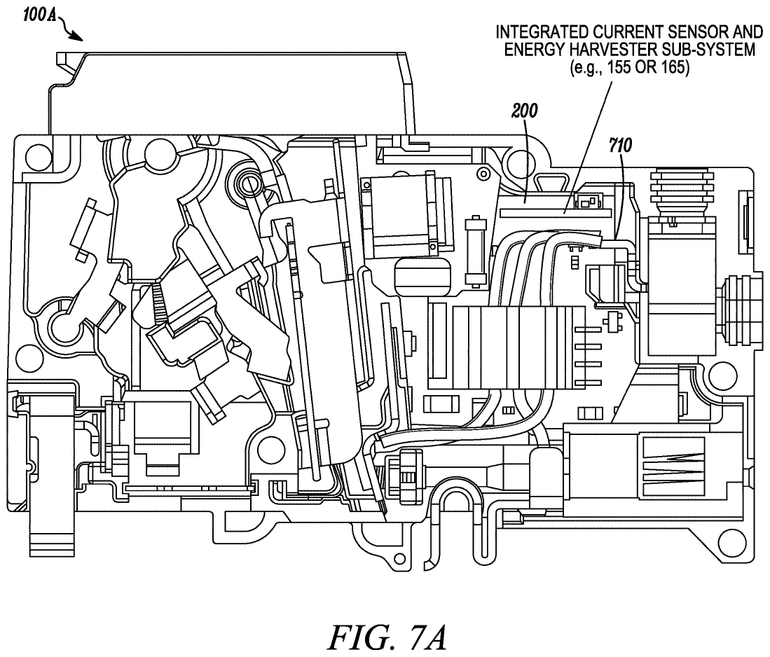

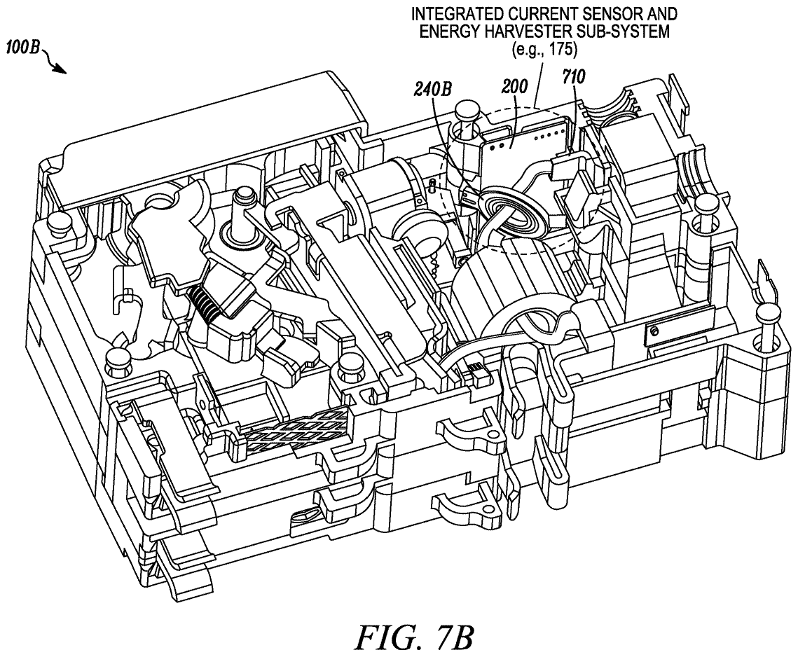

FIG. 7A shows a view of a current flow monitoring device such as a circuit protective device 100A (e.g., a 2-pole circuit breaker), without a portion of a cover/base/housing to show example components thereof, in accordance with embodiments of the present disclosure. The example components can include load-side connectors, line-side connectors, main conductors (e.g., L1, L2 and N), trip circuit, coils and mechanism, PCBA with CPU (e.g., MCU or main MCU) and other electronical components, actuator circuit and actuator, operating mechanism (e.g., handle, etc.), communication circuit/device(s) and other components including other components known to be employed in a breaker, such as for example, a miniature circuit breaker (MCB). The circuit protective device 100A can also include one or more integrated multifunctional energy systems, e.g., 155 or 165, to monitor current flow on respective one or more electrical conductors such as one or more line conductors and to harvest energy from current flow on the one or more conductors.

In this example, each integrated energy system 155, 165 can include a non-invasive, low-profile current sensor and energy harvester (on the substrate 200), which can be positioned in proximity and in parallel (or substantially parallel) to a respective electrical conductor to be monitored, such as near a conductive load-side lug 710 of a load-side terminal connection, which terminates the conductor such as a line conductor, in order to monitor the current flowing through the line conductor. In this example, the integrated energy system 155, 165 can be connected or mounted into the base, cover or housing of the circuit breaker 100A, such as into a slot, groove or cavity designed in an interior wall or structure of the base, cover or housing to receive the sensor, in proximity and in parallel (or substantially parallel) to a portion of the electrical conductor to be monitored. The base, cover or housing, including some internal structures or walls, of the breaker 100A can be made of plastic, which can be molded into a designed shape. The slots, grooves, or cavities for the integrated energy system 155, 165 can be molded on or cut into the base or cover at desired location to monitor desired conductor(s), such as near a lug terminal, bus bar, bonding wire, or other conductor or conductive structure. Along these lines, the integrated energy system 155, 165 also can be connected onto or formed as part of other components or structure of the breaker 100A, including but not limited to the PCBA with the MCU (or main MCU) of the breaker 100A, other PCBs in the breaker 100A, or other fixed structure or component in the breaker 100A.

FIG. 7B shows a view of a current flow monitoring device such as a circuit protective device 100B (e.g., a 2-pole circuit breaker), without a portion of a cover/base/housing to show example components thereof. The circuit protective device 100B is basically the same as the circuit protective device 100A of FIG. 7A, except that the circuit protective device 100B employs one or more integrated multifunctional energy systems, e.g., 175, to monitor current flow on respective one or more electrical conductors such as one or more line conductors and to harvest energy from the current flow on the one or more conductors.

In this example, each integrated energy system 175 can include a non-invasive, low-profile resonator-based energy harvester and a low-profile PCB trace sensor 240B on the substrate 200. The energy harvester can be positioned in proximity and in parallel (or substantially parallel) to a respective electrical conductor to be monitored, such as near a conductive load-side lug 710 of a load-side terminal connection, which terminates the conductor such as a line conductor, in order to monitor the current flowing through the line conductor. A portion of the electrical conductor also can be positioned in the opening of the PCB trace sensor 240B of the integrated energy system 175. In this example, the integrated energy system 175 or a portion thereof (e.g., substrate 200 with the components of the energy harvester) can be connected or mounted into the base, cover or housing of the circuit breaker 100B, such as into a slot, groove or cavity designed in an interior wall or structure of the base, cover or housing to receive the portion, in proximity and in parallel to a portion of the electrical conductor to be monitored. The base, cover or housing, including some internal structures or walls, of the breaker 100B can be made of plastic, which can be molded into a designed shape. The slots, grooves, or cavities for the integrated energy system 175 can be molded on or cut into the base or cover at desired location to monitor desired conductor(s), such as near a lug terminal, bus bar, bonding wire, or other conductor or conductive structure. Along these lines, the integrated energy system 175 or portion thereof also can be connected onto or formed as part of other components or structure of the breaker 100B, including but not limited to the PCBA with the MCU (or main MCU) of the breaker 100B, other PCBs in the breaker 100B, or other fixed structure or component in the breaker 100B.

The examples in FIGS. 7A and 7B show the versatility of the integrated multifunctional energy systems 155, 165 and 175 and their components (e.g., sensor, energy harvester, etc.), which can allow them to be installed in areas of a breaker that are typically unsuited for installation of other types of sensors or other devices, such as conventional CT sensors. As shown, the resonator and energy transducer(s) for the sensor and/or energy harvester of the integrated energy system 155, 165, 175 can be designed to have a low-profile, e.g., a size of 0.2 cm³, versus a 13-turn CT which has a size of about 1.5 cm³. Accordingly, the non-invasive and low-profile characteristics of the sensor and energy harvesting components (e.g., micro-resonator, energy transducer(s) and/or PCB trace sensor) of such integrated multifunctional energy systems can provide greater flexibility in the design, installation, and manufacture of breakers and their components, particularly where space is limited.

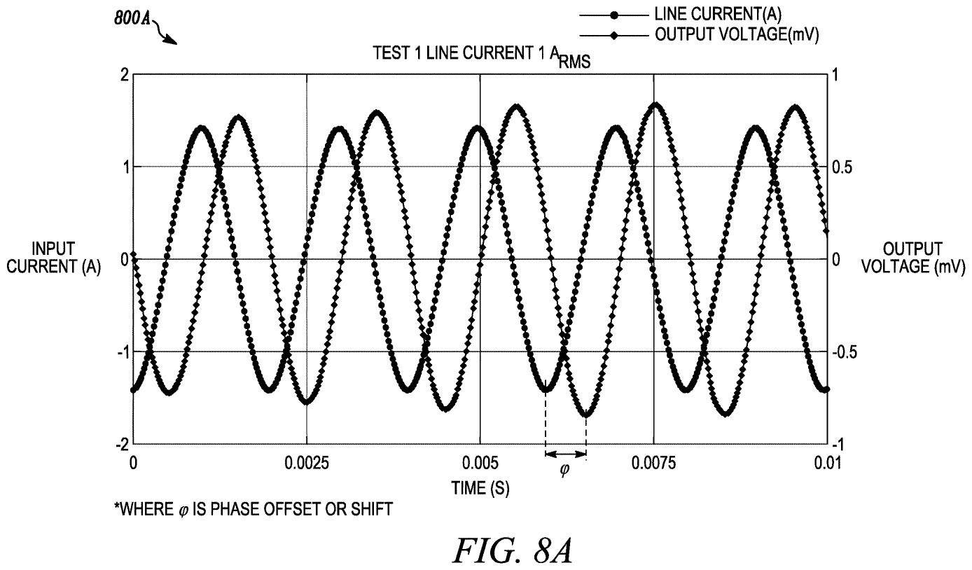

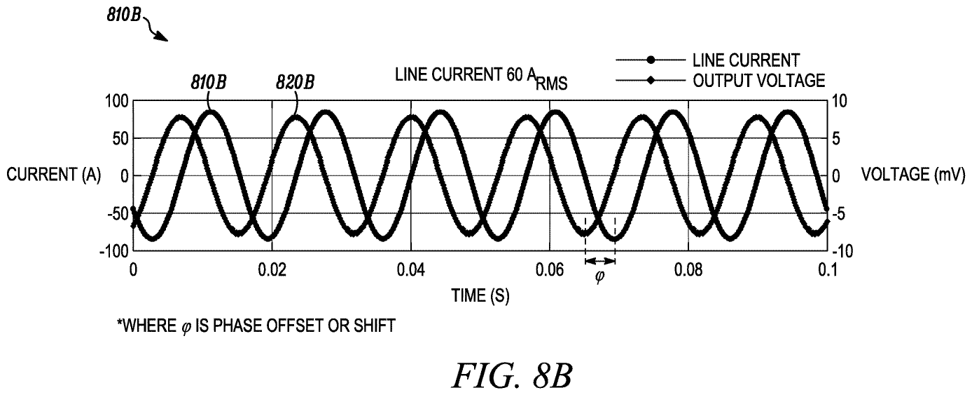

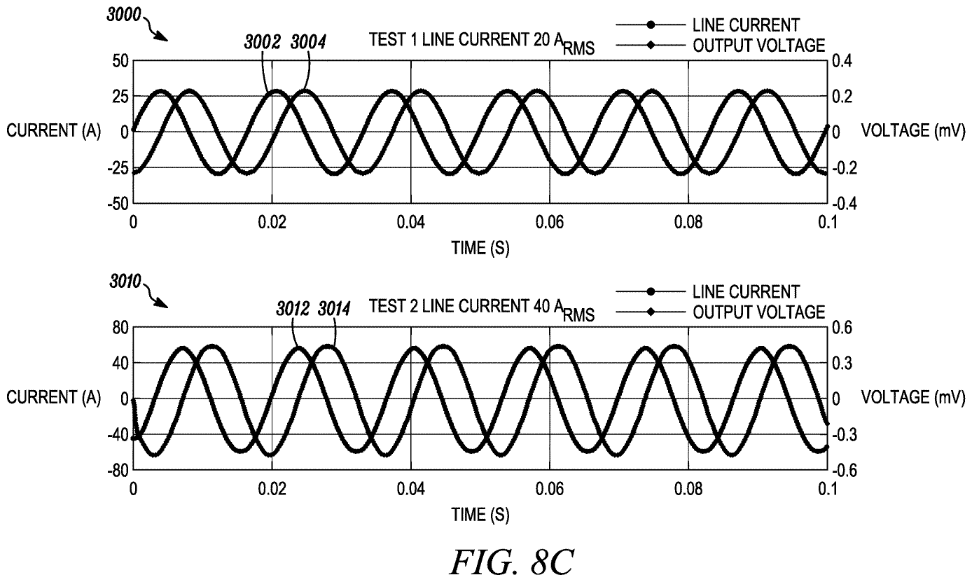

FIG. 8A shows a graph 800A illustrating performance under test conditions for a non-invasive, low-profile current sensor with a mechanical resonator with a magnet-suspension assembly, and an electrodynamic/electromagnetic transducer such as shown in the example of FIG. 2A, according to embodiments of the present disclosure. In the graph, the left vertical axis represents input current (in Amp (A)), and the right vertical axis represents current sensor voltage (in mV or millivolts), and the horizontal axis represents time (in seconds). The graph 800A shows the results of testing using a line current of 1 Amp RMS. Current waveform 810A represents the line current and voltage waveform 820A represents the voltage signal produce by the non-invasive, low-profile current sensor (and conditioned by a signal processing front end) in response to the line current. As can be seen, the voltage waveform 820A closely tracks the current waveform 820A, indicating that the current sensor was able to accurately sense the line current.

In various embodiment, as to any potential phase difference o between the input current and the output voltage of the current sensor, a phase offset, e.g., a predefined phase offset, may be applied to the output voltage to calibrate the measurement of the current sensor. The predefined phase offset can be determined based on testing of the current sensor before or after installation into a circuit protective device (e.g., at the factory, at the work site, etc.).

FIG. 8B shows a graph 800B illustrating performance under test conditions for a non-invasive, low-profile PCB planar trace current sensor, such as shown in the example of FIG. 2B, according to embodiments of the present disclosure. In the graph, the left vertical axis represents input current (in Amp (A)), and the right vertical axis represents current sensor voltage (in mV or millivolts), and the horizontal axis represents time (in seconds). The graph 800B shows the results of testing using a line current of 60 Amp RMS. Current waveform 810B represents the line current and voltage waveform 820B represents the voltage signal produce by the non-invasive, low-profile current sensor (and conditioned by a signal processing front end) in response to the line current. As can be seen, the voltage waveform 820B closely tracks the current waveform 820B, indicating that the current sensor was able to accurately sense the line current.

In various embodiment, as to any potential phase difference o between the input current and the output voltage of the current sensor, a phase offset, e.g., a predefined phase offset, may be applied to the output voltage to calibrate the measurement of the current sensor. The predefined phase offset can be determined based on testing of the current sensor before or after installation into a circuit protective device (e.g., at the factory, at the work site, etc.).

Referring now to FIG. 8C, graphs are shown illustrating performance under test conditions for a PCB trace current sensor such as shown in the example of FIG. 2C, according to embodiments of the present disclosure. In both graphs, the left vertical axis represents test current, the right vertical axis represents current sensor voltage, and the horizontal axis represents time. The first graph, indicated at 3000, shows the results of testing using a line current of 20 Amps RMS. Current waveform 3002 represents the line current and voltage waveform 3004 represents the voltage signal produce by the PCB trace current sensor (and conditioned by a signal processing front end) in response to the line current. As can be seen, the voltage waveform 3004 closely tracks the current waveform 3002, indicating that the PCB trace current sensor was able to accurately sense the line current. The second graph, indicated at 3010, shows the results of testing using a line current of 40 Amps RMS. Current waveform 3012 represents the line current and voltage waveform 3014 represents the voltage signal produce by the PCB trace current sensor in response to the line current. Again, it can be seen that the voltage waveform 3014 closely tracks the current waveform 3012, indicating that the PCB trace current sensor was able to accurately sense the line current.

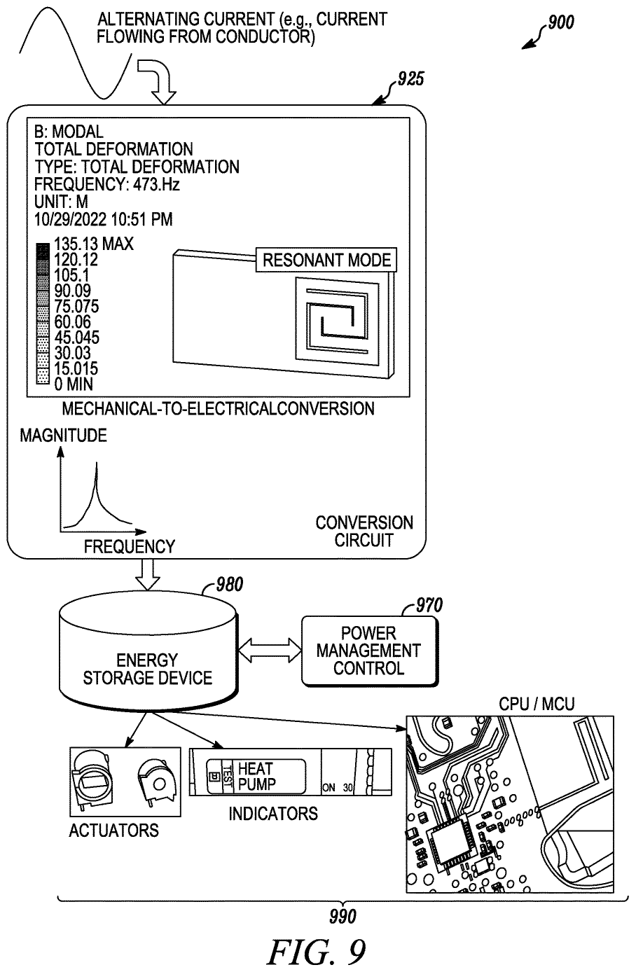

FIG. 9 shows an exemplary diagram of an energy harvesting sub-system 900 of a circuit protective device, such as a circuit breaker, which employs the non-invasive, low-profile resonator-based current sensor and/or energy harvester as described herein, according to embodiments of the present disclosure. In general, the sensor and/or energy harvester can include a conversion circuit 925 to convert mechanical energy from the oscillations of a magnet-suspension assembly of a mechanical resonator to electrical energy. As previously explained, the magnet-suspension assembly can be configured to oscillate due to the varying magnetic field from current, such as AC current, flowing through a conductor to be monitored. The conversion circuit 925 can be an electromechanical transducer, e.g., a piezoelectric transducer, etc., which converts the mechanical energy from the oscillations to electrical energy. The electrical energy generated by the electromechanical transducer can be harvested and stored in an energy storage device 980 (e.g., after conditioning and conversion as needed based on the application).

A power management control 970 can be provided in the breaker to manage the storage and usage of the electrical energy harvested from the electromechanical transducer. For example, the harvested electrical energy can be used to power components and circuits of the breaker, such as actuator(s), indicator(s), CPU/MPU and so forth. In various embodiments, the harvested electrical energy can be used as the primary source of power, or a backup power source under control of the power management control 970. Furthermore, in various embodiments, the harvested energy can be used to power component(s) or circuit(s) of the sensor.

FIGS. 10, 11 and 12 show different views of a non-invasive, low-profile current resonator-based sensor and/or energy harvester and its components of an integrated multifunctional energy system (e.g., 155, 165 or 175), according to embodiments of the present disclosure. In this example, the integrated energy system can include a “dual-transduction” or “dual-mode” sensor for providing the dual functionality of current monitoring and energy harvesting. The integrated energy system can employ in combination with a mechanical resonator, a first energy transducer such as an electrodynamic transducer (e.g., coil(s)) for monitoring current on a conductor, and a second energy transducer such as an electromechanical transducer for energy harvesting. The electromechanical transducer is a piezoelectric transducer.

The nature or characteristics of the two energy transducers makes the electrodynamic transducer (e.g., coil(s)) better suited for monitoring applications, and the electromechanical transducer, such as a piezoelectric transducer, better suited for energy harvesting. For example, electrodynamic transducers generally produce lower voltage and higher currents, whereas piezoelectric transducers produce higher voltages and lower currents; or, equivalently, electrodynamic transducers have lower output impedance than piezoelectric transducers. Higher output voltages are generally desired to enable higher power efficiency in the power management electronics that are required to convert the AC power waveforms into stable DC waveforms for charging capacitors, batteries or even powering devices such as sensors or electronic circuits. Design objective of dual-transduction micro-resonator sensor can be to simultaneously generate higher voltages than a pure electrodynamic transducer and higher time-average power than a pure piezoelectric transducer, while maintaining a low-profile.

As shown in FIGS. 10, 11 and 12, the dual-transduction sensor of the integrated energy system can include a mechanical resonator, a first energy transducer including coil(s) 1050 (Electrodynamic Transducer), and a second energy transducer such as piezoelectric element(s) 1060 (Piezoelectric Transducer). The magnet-suspension assembly of the mechanical resonator includes a suspension 1010, a permanent magnet 1030, and a spacer 1020 connected between the suspension 1010 (or a component thereof) and the magnet 1030. The suspension 1010 includes a base frame (or anchor base) 1012, a center platform 116, and two meandering suspension elements 1014 (e.g., meandering suspension arms, beams, segments or elements). The coil 1050 of the first energy transducer is positioned or arranged in proximity around (or to surround) the magnet 1030 or a portion thereof. The piezoelectric elements 1060 of the second energy transducer are connected to the suspension 1010 or component(s) thereof.

In this example, the sensor is a dual-function sensor, which employs a double-clamped meandering titanium suspension 1010, two piezoceramic (or ceramic piezoelectric) elements 1060 attached to the clamped arms of the meandering suspensions 1014, and a laterally magnetized square-shape permanent magnet 1030 attached to the center platform 1016 (on the side opposite to the base frame 1012 so that it surrounds the magnet 1030).

The operation of the dual-transduction sensor can rely on a resonant structure combining both electrodynamic and piezoelectric transductions. Under the influence of the time-varying magnetic field created by the AC current flowing through the monitored conductor of a current flowing monitoring device (e.g., breaker 100 of FIG. 1A), the structure of the sensor 125 can generate electrical power while oscillating in torsional resonance. The spacer 1020 (e.g., a silicon spacer) can provide clearance between the magnet 1030 and the suspension 1010 (or component(s) thereof) during torsional oscillation. The two piezoelectric elements 1060 are connected electrically in series. The leads of the coil 1050 are independent of the leads of the piezoelectric elements 1060, so that the system has two simultaneous power generation output ports. By placing the micro-resonator sensor under a spatially distributed, time varying magnetic field of desired frequency and amplitude, a torsional vibration is produced due to a torque induced on the resonator's magnet 1030. This generates a dynamic stress on the piezoelectric elements which is then converted into electricity by means of the piezoelectric effect. Simultaneously, the motion of the magnet induces an electromotive force (EMF) in the micro-resonator's coil(s) 1050 by means of Faraday's law of induction. In both transduction modes, maximum voltage and power generation can be achieved at the torsional resonance of the mechanical suspension and when the receiver is oriented perpendicular to the applied magnetic field.

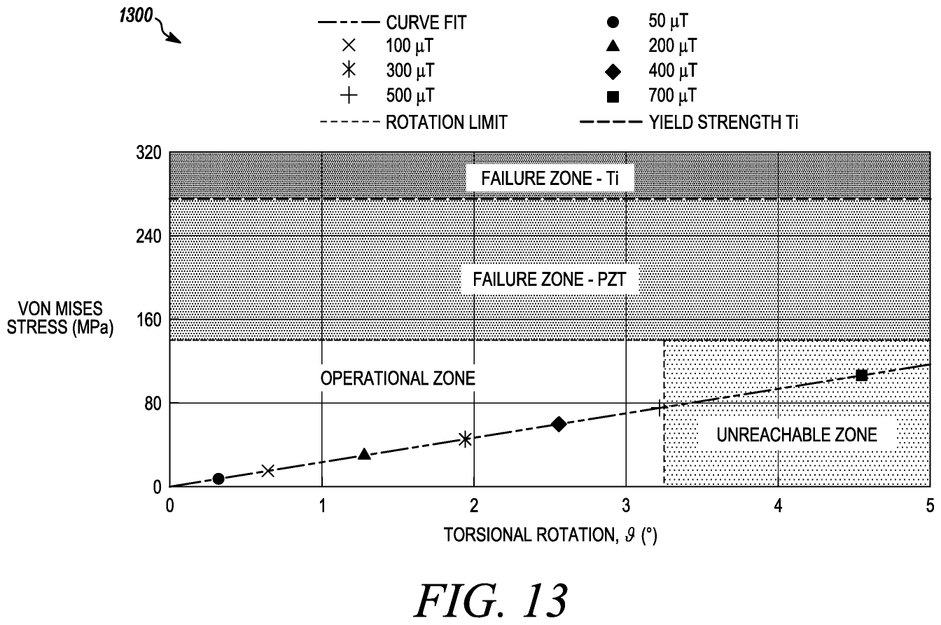

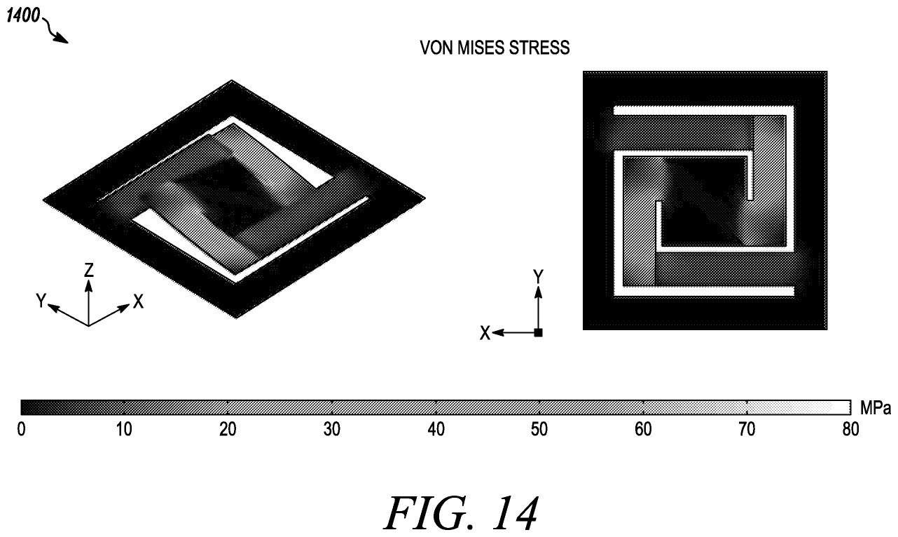

To understand the mechanical reliability of the micro-resonator-based sensor, stress distribution simulations have been performed considering the example dual-transduction micro-resonator of FIGS. 10 through 12. To that end, various magnetic field amplitude excitations at resonance are considered. Two mechanical limits are considered: (a) the maximum rotation angle at which the magnet 1030 comes in contact with the clamped arms of the meandering suspension 1014 (±3.25° for the dual-transduction design) and (b) the threshold rotation angle where any portion of the suspension reaches its yield stress. Considering the ductility of titanium, it is assumed gradual failure mode would occur whenever the equivalent von Mises stress exceeds the tensile yield strength of titanium (assumed to be 275 Mpa). For the piezoelectric elements, the tensile yield strength of PZT-5A (assumed to be 140 Mpa) was used. FIG. 13 shows an example failure diagram 1300 for the von Mises stress plotted against rotation angle. From the diagram of FIG. 13, it appears that the magnet 1030 will interfere with the suspension base before exceeding one of the stress-related failure limits. As illustrated on the graph 1400 in the example of FIG. 14, at the maximum rotation angle of ±3.25°, the maximum stress is only about 80 Mpa, which is far below the failure limit for PZT-5A (or Titanium (Ti)). Such mechanical reliability evaluation can be considered when designing resonators for desired applications.

In accordance with various embodiment, a micro-resonator for applications at or around 50 Hz or 60 Hz frequency can be designed, according to size, shape, dimensions, materials of the magnet-suspension assembly and its components such as the suspension (and component(s) thereof). The design of the suspension can employ a base frame, for example, having a dimension 7.6 mm×7.6 mm, with desired shape, pattern, dimension, and location for the suspension arms such as a meandering shape and for the platform. It should be understood that the micro-resonator also can be designed for applications at or around other desired frequencies.

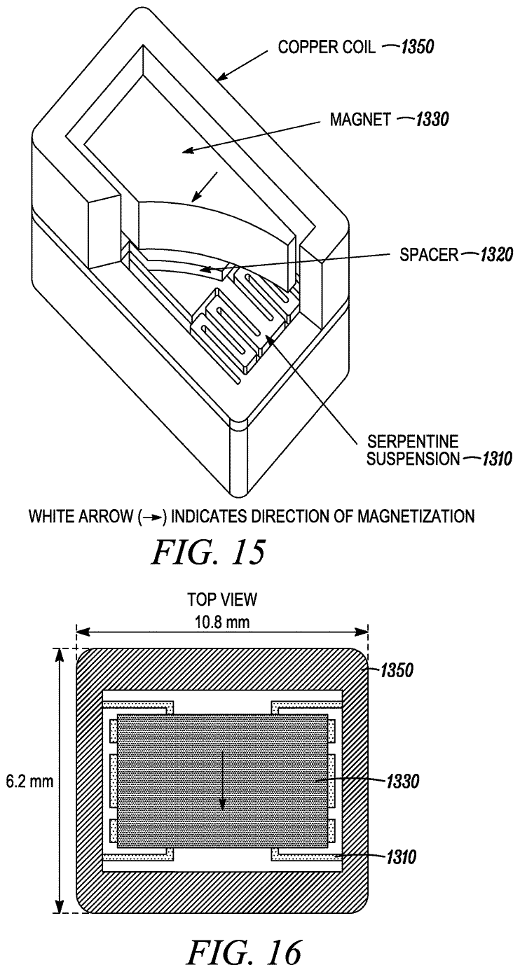

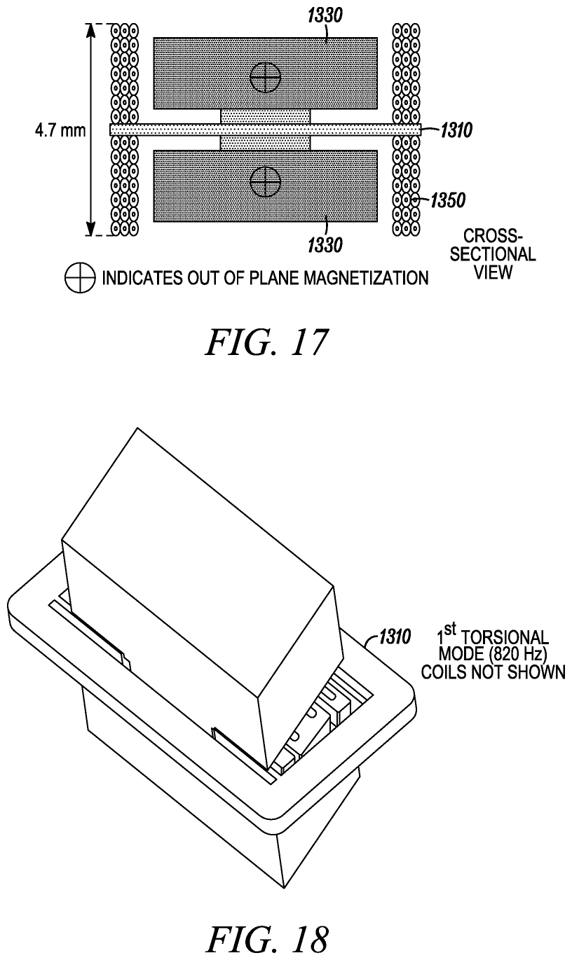

FIGS. 15, 16, and 17 show exemplary components of a resonator-based sensor and/or energy harvester, according to various embodiments of the present disclosure. In this example, the sensor and/or energy harvester includes at least a mechanical resonator and an energy transducer such as an electrodynamic transducer, e.g., coil(s) 1350. The coil 1350 can be a copper coil. The mechanical resonator can include a magnet-suspension assembly, which includes a suspension 1310, a magnet 1330 (e.g., a permanent magnet), and a spacer 1320 connected between the magnet 1330 and suspension 1310. In this example, there are two magnets 1330 on opposite sides of the suspension 1310, which are both connected to a corresponding side of the suspension 1310 across a corresponding a spacer 1320. The suspension 1310 can have a serpentine design, e.g., meandering suspension element(s) with a serpentine design between a central platform and base frame. Each of the magnets 1330 can have an associated coil 1350, which is arranged in proximity around a respective magnet-suspension sub-assembly on each side (e.g., top side and a bottom side) of the suspension 1310. The direction of magnetization is shown in FIGS. 15 and 16, and the out of plane magnetization is shown in FIG. 17. The resonator-based sensor and/or energy harvester in this example can have an overall dimension of 10.8 mm×6.2 mm×4.7 mm (Length×Width×Height). As further shown in the example of FIG. 18, the suspension 1310 with a serpentine design (or serpentine suspension elements) can have a first torsional mode (820 Hz).

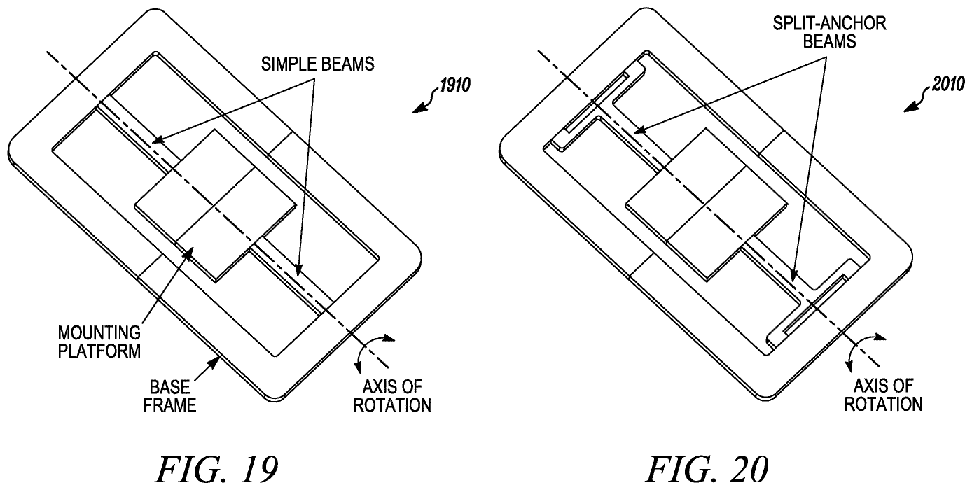

FIGS. 19, 20, 21, and 22 show different example designs of different suspensions 1910, 2010, 2110, and 2210 respectively for the magnet-suspension assembly of a mechanical resonator, such as for the example non-invasive, low-profile current micro-resonator sensor and/or energy harvester of FIGS. 15 through 17 and other micro-resonator sensors or energy harvesters as described herein, according to embodiments of the present disclosure. For each type of suspension, an axis of torsional rotation is shown extending centrally across the suspension along a direction of their beams. The design of the suspensions can be symmetrical relative to the axis of rotation, e.g., an axis of symmetry.

The example suspension 1910 in FIG. 19 can have a simple beam design, with two straight beam suspension segments, each connected between a central mounting platform and a base frame from opposing sides of the base frame. The beams are aligned along a length of the suspension 2010.

The suspension 2010 in FIG. 20 can have a split-anchor beam design, with two split-anchor suspension beams, each connected between a central mounting platform and a base frame from opposing sides of the base frame. The beams are aligned along a length of the suspension 2110.

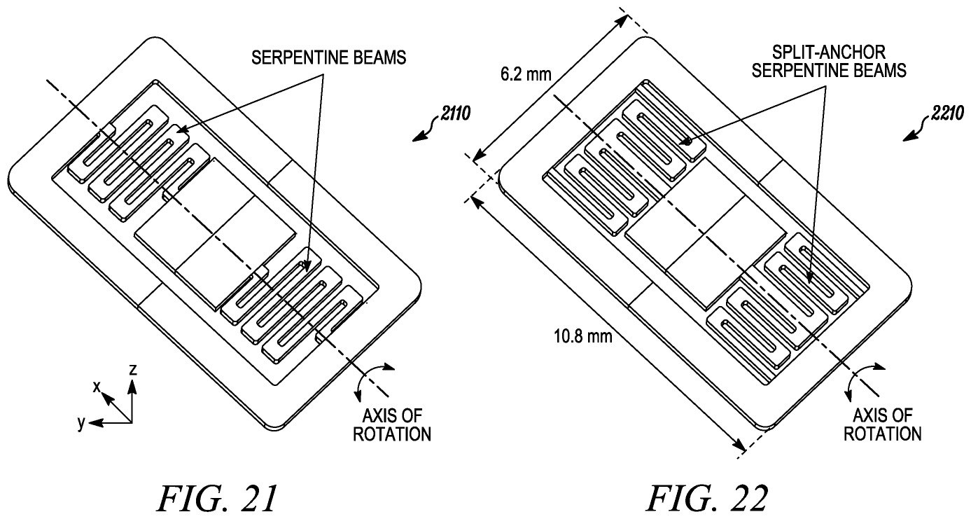

The suspension 2110 in FIG. 21 can have a serpentine beam design, with two serpentine suspension beams, each connected between a central mounting platform and a base frame from opposing sides of the base frame.

The suspension 2210 in FIG. 22 can have a split-anchor serpentine beam design, with two serpentine split-anchor suspension beams, each connected between a central mounting platform and a base frame from opposing sides of the base frame.

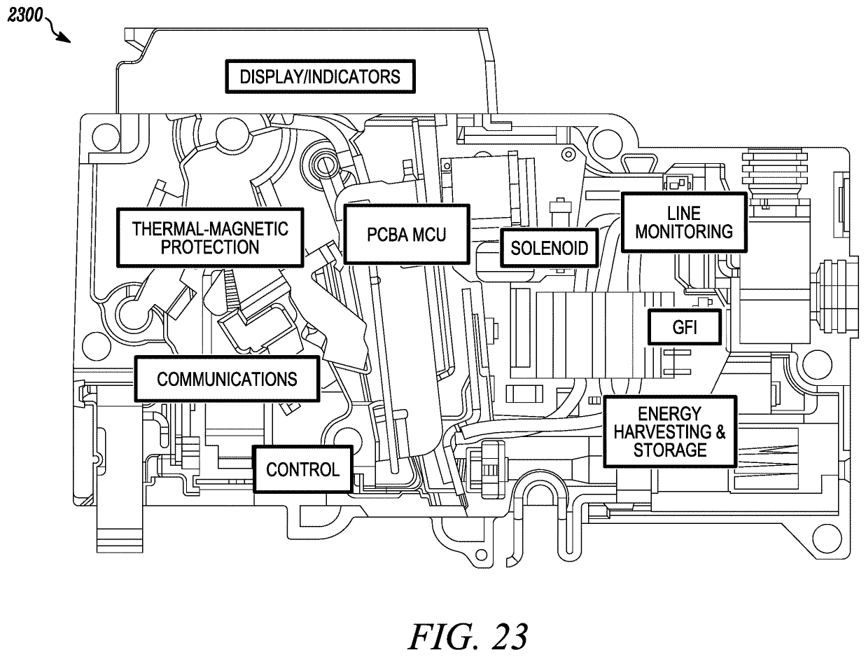

FIG. 23 shows an exemplary functional block diagram of a circuit protective device, such as a miniature circuit breaker 2300. The circuit breaker can include various example functions, features, and hardware. As shown, these functions, features and hardware can include a controller (e.g., MCU) on a printed circuit board assembly (PCBA) to control the operations and components of the breaker, a solenoid to trip a tripping device or circuit (e.g., switch, relay, etc.) to interrupt power to a circuit in response to certain detected conditions (e.g., fault, overload, short-circuit, etc.), ground fault interrupt (GFI), line monitoring, energy harvesting and storage, control, communications, thermal-magnetic protection, and display/indicators, among other things. The breaker 2400 can employ one or more non-invasive, low-profile micro-resonator sensors and/or energy harvesters in various embodiments as described herein to provide functionality for current monitoring and/or energy harvesting.

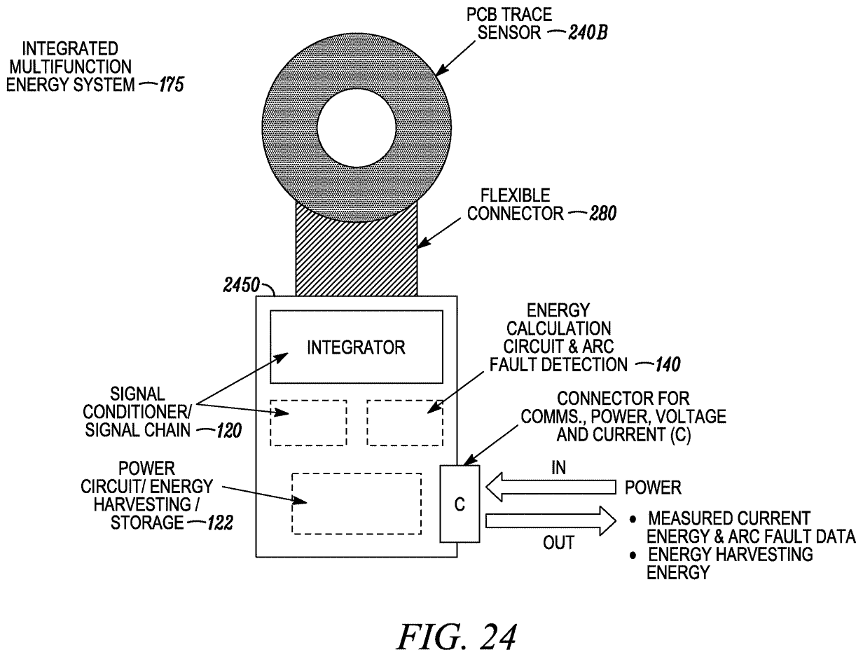

FIG. 24 shows an example of an integrated multifunctional energy system 175 (e.g., 175A or 175B), for current sensing and energy harvesting according to embodiments of the present disclosure. In this example, the integrated energy system 175 can include a PCB trace sensor 240B with a flexible connector 280 for connecting to other electronic/electrical component(s), including a resonator-based energy harvester, on another PCB substrate (or section). The integrated energy system 175 can be employed to monitor energy-related signals (e.g., current or voltage) on a conductor, such as for example in the current flow monitoring device 100, breaker or other devices described herein.

The integrated energy system 175 can be a PCB module that includes a first PCB sub-module and a second PCB sub-module, which are connected across the flexible connector 280. The first PCB sub-module can include the PCB trace sensor 240B. The second PCB sub-module can be a signal chain and energy monitoring PCB board (or substrate) 2450, which can include a separate PCB section/substrate, having various electronic/electrical components. The electronic/electrical component(s) can include a signal conditioning circuit or conditioner 120 (e.g., a signal integrator, signal chain, etc.) for processing signals received from the PCB trace sensor 240B across the flexible connector 280; a power supply circuit 122 which can include the resonator-based energy harvester, energy storage and a power bus system; and a connector (or connector interface) C for connecting to other electronic/components in the monitoring device. The board 2450 also can include other signal processing circuits, such as energy measurement/calculation circuit (e.g., Energy Integrated Circuit (IC)) and arc fault detection circuit (e.g., Arc Det.). The connector C can be used to receive as input measured line voltage and power supply voltage from which the power supply circuit can supply power to various electronic/electrical components of the board 2450, and to output measured line current and arc fault data to other remote electronic/electrical component(s) of the current flow monitoring device such as a main controller (e.g., MCU or CPU) of the monitoring device for further processing and action. The further processing and action can, for example, include tripping the breaker, generating an alarm, reporting measurements and/or other relevant information, and so forth.

In various embodiments, the energy system(s) 175 can be employed to measure energy-related signals, e.g., current or voltage, on a conductor using the PCB trace sensor 240B in a 1-pole or multi-pole monitoring device, such as a 1-pole or multi-pole breaker, and process measurement signals from the sensor as described herein. In various embodiments, a plurality of energy systems 175 can be employed to measure energy-related signals (e.g., current or voltage) on a plurality of conductors using a plurality of PCB trace sensors 240B in a multi-pole current flow monitoring device, such as a 2-pole breaker, and to process the measurement signals from corresponding sensors. An example of first and second energy systems 175 (e.g., 175A and 175B) are shown in the example of FIG. 1C for a 2-pole current flow monitoring device, such as a 2-pole miniature circuit breaker. In the example of FIG. 1C, each energy system 175 can be used to monitor and process measurements of energy-related signals (e.g., current or voltage) for respective line conductors (e.g., Line 1 and Line 2). In the energy system 175, an energy harvester also can be provided to harvest energy from a monitored conductor using a low-profile micro-resonator and energy transducer, such as described herein.

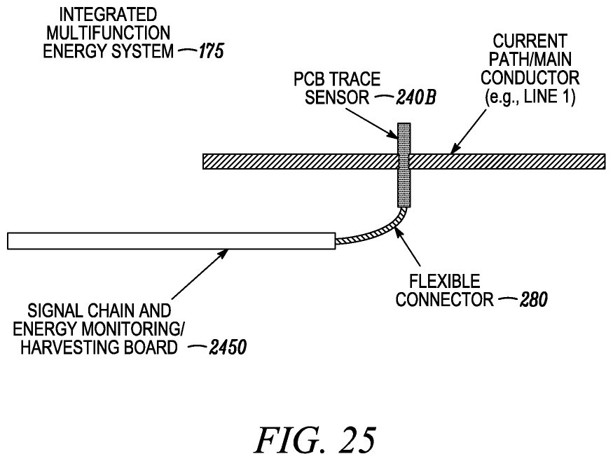

FIG. 25 shows a side view of an example of the integrated multifunctional energy system 175, which includes a PCB trace sensor with a flexible connector for connecting to other electronic/electrical component(s) on another PCB section/substrate, according to embodiments of the present disclosure. The energy monitoring sub-system 2500 can include a first PCB sub-module, a second PCB sub-module, and a flexible connector 280 for connecting the first and second PCB sub-modules (or components thereof). The first PCB sub-module can include the PCB trace sensor 240B. The second PCB sub-module can be a separate PCB section/substrate such as for example a signal chain and energy monitoring board 2450, which can incorporate a low-profile energy harvester that uses a micro-resonator and transducer (as described herein). The board 2450 can be a main breaker PCBA, or other printed circuit board as described herein.

As shown in FIG. 25, the PCB trace sensor 240B can be arranged in a current flow monitoring device to measure energy-related signals on a conductor. The flexible connector 280 can be adjustably bent to position the PCB trace sensor 240B and board 2450 in a case or housing of a current flow monitoring device as well as to align component(s) of the energy harvester (e.g., in parallel) with a conductor (e.g., a monitored conductor) to facilitate energy harvesting.

It should also be understood that the example embodiments disclosed and taught herein are susceptible to numerous and various modifications and alternative forms. Thus, the use of a singular term, such as, but not limited to, “a” and the like, is not intended as limiting of the number of items. Furthermore, the naming conventions for the various components, functions, characteristics, thresholds, and other elements used herein are provided as examples, and can be given a different name or label. The use of the term “or” is not limited to exclusive “or”, but can also mean “and/or”.

While particular embodiments and applications of the present disclosure have been illustrated and described, it is to be understood that the present disclosure is not limited to the precise construction and compositions disclosed herein and that various modifications, changes, and variations can be apparent from the foregoing descriptions without departing from the invention as defined in the appended claims. It is understood that components, features and functionality in various embodiments as described herein can be incorporated into other embodiments.

While several embodiments of the present disclosure have been shown and described herein, it is to be understood that the above description is intended to be illustrative, and not restrictive. Many other implementation examples are apparent upon reading and understanding the above description. Although the disclosure describes specific examples, it is recognized that the systems and methods of the disclosure are not limited to the examples described herein, but may be practiced with modifications within the scope of the appended claims. Accordingly, the specification and drawings are to be regarded in an illustrative sense rather than a restrictive sense. The scope of the disclosure should, therefore, be determined with reference to the appended claims, along with the full scope of equivalents to which such claims are entitled.

1. An integrated multifunctional energy system comprising:
a resonator comprising an oscillatable suspension assembly which includes a suspension and a magnetodynamic volume, the suspension having a platform on which the magnetodynamic volume is connected, the suspension assembly being configured to oscillate under an influence of a time-varying magnetic field generated by the flow of current through the conductor which is arranged in proximity to the suspension assembly or component(s) thereof; and
a first energy transducer, positioned around or in proximity to at least a portion of the magnetodynamic volume, on or through which an electromagnetic force is induced by the oscillation of the magnetodynamic volume(s) to generate electrical energy comprising an output voltage or current that is proportional to the current flowing through the conductor.

2. The integrated multifunctional energy system according to claim 1,
wherein the magnetodynamic volume comprises a permanent magnet, a magnetostrictive material or a combination thereof;
the first energy transducer comprises an electromechanical transducer, a piezoelectric transducer, or a magneto-electric transducer.

3. (canceled)

4. The integrated multifunctional energy system according to claim 1, comprising: at least a current sensor for sensing current flow through the conductor and an energy harvester for harvesting energy from current flow through the conductor, the current sensor and energy harvester being provided as an integrated system, wherein the resonator is a component of the current sensor, the energy harvester, or both.

5. The integrated multifunctional energy system according to claim 4, further comprising a printed circuit board trace sensor, wherein the current sensor comprises the printed circuit board trace sensor, and the energy harvester comprising the resonator and the first energy transducer;
components of the current sensor and the energy harvester are provided on the same printed circuit board substrate, or provided on different printed circuit board substrates which are connected across a flexible connector.

6. (canceled)

7. The integrated multifunctional energy system according to claim 1, wherein the suspension assembly further includes a spacer(s) connected between the platform and the magnetodynamic volume;
the suspension further comprises a base or mounting frame and at least one arm, beam, segment or element connected on one end to the base or mounting frame and on another end to the platform.

8. (canceled)

9. The integrated multifunctional energy system according to claim 1, wherein the suspension includes simple beam(s), split-anchor beam(s), serpentine beams(s), split-anchor serpentine beam(s) and/or meandering beam(s), which is connected to a base or mounting frame and the platform.

10. The integrated multifunctional energy system according to claim 1, wherein the suspension and/or a component(s) thereof is made of titanium or titanium alloy, aluminum or aluminum alloy, or a non-magnetic alloy.

11. The integrated multifunctional energy system according to claim 1, wherein the electrical energy generated by the first energy transducer is harvested and used to provide a measurement of the current flow.

12. The integrated multifunctional energy system according to claim 1, further comprising:
a second energy transducer for generating electrical energy from oscillation of the suspension assembly, the electrical energy generated by one of the first and second energy transducers being used for measurement of the current flow through the conductor, the electrical energy generated by the other one of the first and second energy transducers being used for harvesting energy.

13. The integrated multifunctional energy system according to claim 12, wherein the first energy transducer or the second energy transducer comprises an electromechanical transducer, a piezoelectric transducer, or a magneto-electric transducer;
the first energy transducer or the second energy transducer comprises the piezoelectric transducer, the piezoelectric transducer having two piezoelectric arms, segments or elements, each of which is connected at one end to the suspension or a component(s) thereof.

14. (canceled)

15. The integrated multifunctional energy system according to claim 12, further comprising:
a third energy transducer or planar coil current sensor for generating electrical energy which is proportional to the current flow through the conductor,
wherein the electrical energy generated by one of the first and second energy transducers is used for measurement of the current flow through the conductor in a first frequency range, and the electrical energy generated. by the third energy transducer or planar coil current sensor is used for measurement of the current flow through the conductor in a second frequency range which differs from the first frequency range.

16. The integrated multifunctional energy system according to claim 1, further comprising a printed circuit board substrate or other non-conductive substrate on or to which at least the electrodynamic coil and the resonator are connected, the printed circuit board substrate or other non-conductive substrate having a hole, opening or cavity which has the electrodynamic coil and at least a portion of the magnetodynamic volume arranged therein in proximity to each other.

17. The integrated multifunctional energy system according to claim 1, wherein the resonator is configured for an application at or around 50 Hz or 60 Hz.

18. The integrated multifunctional energy system according to claim 1, wherein the resonator is a micro-resonator.

19. The integrated multifunctional energy system according to claim 1, wherein a portion of the conductor is arranged in proximity and in parallel or substantially parallel to the magnetodynamic volume of the suspension assembly.

20. The integrated multifunctional energy system according to claim 1, wherein the suspension assembly or component(s) thereof is configured to oscillate in torsional resonance under the influence of the time-varying magnetic field generated by a flow of AC current through the conductor.

21. The integrated multifunctional energy system according to claim 1, wherein the output voltage or current is shifted by a phase offset to calibrate a measurement of the current flowing through the conductor.

22. A circuit protective device comprising:
the conductor;
at least one of the integrated multifunctional energy system according to claim 1; and
a processor(s) configured to:
detect for a condition or fault on a circuit of an electrical system based on the current monitored on the conductor of the circuit by the sensor system; and
interrupt the flow of current on the conductor if the condition or fault is detected.

23. The circuit protective device according to claim 22, wherein the electrical system is a multi-phase or pole electrical system, the conductor comprises a plurality of line conductors for multi-phases or multi-poles of the electrical system, and the at least one of the integrated multifunctional energy system comprises a plurality of the integrated multifunctional energy systems for the plurality of line conductors.

24. A method of non-invasively monitoring a flow of current flow through a conductor and/or harvesting energy due to current flow through the conductor, the method comprising:
providing a resonator comprising an oscillatable suspension assembly including a suspension and a magnetodynamic volume, the suspension having a platform on which the magnetodynamic volume is connected, the suspension assembly and components thereof being configured to oscillate under an influence of a time-varying magnetic field generated by the flow of current through the conductor which is arranged in proximity to the suspension assembly or component(s) thereof; and
inducing an electromagnetic force on or through a first energy transducer, which is positioned around and in proximity to at least a portion of the magnetodynamic volume, to produce electrical energy comprising an output voltage or current that is proportional to the current flowing through the conductor,
wherein the resonator and the first energy transducer are integrated onto or into a printed circuit board substrate or other non-conductive substrate as part of an integrated multifunctional energy system.

25. (canceled)

26. (canceled)

27. (canceled)

28. (canceled)

29. (canceled)
